(19) United States
(12) Patent Application Publication
(10) Pub. No.: US 2024/0165575 A1
(43) Pub. Date: May 23, 2024

(54) SYSTEM AND METHODS FOR CHEMICAL SYNTHESIS ON WAFERS

(71) Applicant: Centrillion Technologies, Inc., Palo Alto, CA (US)

(72) Inventors: Bolan LI, Sunnyvale, CA (US); Glenn MCGALL, Palo Alto, CA (US); Filip CRNOGORAC, Redwood City, CA (US); Christopher Alan HACK, Oakland, CA (US); Wei ZHOU, Saratoga, CA (US)

(21) Appl. No.: 17/817,833

(22) Filed: Aug. 5, 2022

Related U.S. Application Data
(63) Continuation of application No. PCT/US2021/017091, filed on Feb. 8, 2021.
(60) Provisional application No. 62/971,224, filed on Feb. 7, 2020.

(51) Int. Cl. B01J 19/00

(52) U.S. Cl. CPC B01J 19/0046; B01J 2219/00283; B01J 2219/00333; B01J 2219/0036; B01J 2219/0047; B01J 2219/00504; B01J 2219/00585; B01J 2219/00722

(57) ABSTRACT

The present disclosure provides methods, device, and system for wafer processing. The wafer processing apparatus uses a nozzle in a lid to disperse a solution to the surface of a wafer. Further, the wafer is positioned on top of a vacuum chuck and does not spin while the solution is dispensed over the surface of the wafer via surface tension, thereby permitting the first solution to react with a reagent on the surface. Further, when dispensing the first solution, a separation gap between the lid and the wafer is at a predetermined distance, for example, from about 20 μm to about 2 mm.

### CROSS-REFERENCE TO RELATED APPLICATIONS

This application is a continuation of International Patent Application No. PCT/US2021/017091, filed Feb. 8, 2021, which claims the benefit of U.S. Provisional Patent Application No. 62/971,224, filed Feb. 7, 2020, the disclosure of each of which is incorporated by reference herein in its entirety.

### SEQUENCE LISTING

This application contains a computer readable Sequence Listing which has been submitted in XML file format via Patent Center, the entire content of which is incorporated by reference herein in its entirety. The Sequence Listing XML file submitted via Patent Center is entitled “14791-039-999_SEQ_LISTING.xml”, was created on Oct. 17, 2023, and is 3,203 bytes in size.

### BACKGROUND

Advances in materials and systems to analyze and characterize biological and biochemical materials have led to improved understanding of the mechanisms of life, health, disease and treatment. For example, genomic sequencing can be used to obtain biomedical information in diagnostics, prognostics, biotechnology, and forensics. The detection of distinctive nucleic acid sequences is critical to many endeavors including identifying microorganisms, diagnosing infectious diseases, detecting genetic abnormalities, identifying biomarker associated with various cancers, rating genetic susceptibility to selected diseases, and evaluating patient's response to medical treatments. Accordingly, oligonucleotide-based deoxyribonucleic acid (DNA) microarrays may become a useful tool for large-scale parallel analyses of genome sequence and gene expression. Current applications of DNA microarrays include global analyses of transcriptional processes, evaluation of clinical course of tumors, and accelerated discovery of drug targets. Manufacturing these oligonucleotide-based DNA microarrays may need reliable chemical synthesis on a solid surface.

### SUMMARY

The present disclosure provides methods, devices and systems for automated high throughput synthesis of chemical entities using low volume chemical reagents on a substrate, for example, in the synthesis of oligonucleotides on a wafer.

An aspect of the present disclosure provides a wafer processing apparatus, comprising: (a) a lower portion; and (b) an upper portion, the upper portion comprising: a bowl affixed to the lower portion; a vacuum chuck disposed in the bowl, the vacuum chuck configured to rotatably hold a wafer; a movable cover disposed above the bowl and configured to engage with the bowl; a lid connected with the movable cover and disposed between the bowl and movable cover, the lid comprising a nozzle at the center of the lid; and three or more adjustment pins, wherein each member of the three or more adjustment pins inserted through an aperture in the movable cover, attached to the lid, and configured to adjust the position of the lid relative to the wafer; wherein the lid and the wafer define a reaction chamber between a bottom surface of the lid and a top surface of the wafer; and wherein the movable cover and the bowl are configured to enclose the vacuum chuck, the wafer, the lid, and the reaction chamber.

In some embodiments of aspects provided herein, the upper portion further comprises an actuator configured to open/close the movable cove. In some embodiments of aspects provided herein, the wafer processing apparatus further comprises a fluidic system comprising a conduit inserted through the movable cover and the lid, and configured to dispense at least one reagent into the reaction chamber via the nozzle. In some embodiments of aspects provided herein, the upper portion further comprises a wafer centering mechanism configured to adjust the position of the wafer, thereby keeping the wafer rotating about a rotation axis of the vacuum chuck. In some embodiments of aspects provided herein, the wafer processing apparatus further comprises a wafer conveyance robot configured to place the wafer onto the vacuum chuck and remove the wafer from the vacuum chuck. In some embodiments of aspects provided herein, the lid is radially smaller than the wafer. In some embodiments of aspects provided herein, at least part of the lid is transparent. In some embodiments of aspects provided herein, at least part of the movable cover is transparent. In some embodiments of aspects provided herein, the wafer processing apparatus further comprises at least one processor configured to control the operation of the movable cover, the vacuum chuck, the lid, the fluidic system, the wafer conveyance robot, the wafer centering mechanism, or a combination thereof. In some embodiments of aspects provided herein, the at least one processor is configured to open/close the movable cover, load/unload the wafer, position the lid, dispense the at least one reagent, synchronize the fluid system, the actuator and the vacuum chuck, or a combination there of.

An aspect of the present disclosure provides a method for processing wafers, comprising: (a) placing a wafer on top of a vacuum chuck of a wafer processing apparatus, the wafer processing apparatus further comprising: (i) a lower portion; and (ii) an upper portion, the upper portion comprising: a bowl affixed to the lower portion; a movable cover disposed above the bowl and engaged with the bowl; a lid connected with the movable cover and disposed between the bowl and movable cover, the lid comprising a nozzle at the center of the lid; and three or more adjustment pins, wherein each member of the three or more adjustment pins inserted through an aperture in the movable cover, attached to the lid; wherein the vacuum chuck is disposed in the bowl, the vacuum chuck configured to rotatably hold the wafer; (b) closing the movable cover, thereby enclosing the wafer in a closed space formed by the movable cover and the bowl; (c) adjusting any of the three or more adjustment pins, thereby making a bottom surface of the lid and the top surface of the wafer substantially parallel and forming a reaction chamber between the bottom surface of the lid and the top surface of the wafer, wherein the width of the reaction chamber ranges from 20 micrometer to 200 micrometer; and (d) dispensing at least one reagent into the reaction chamber by a nozzle; thereby substantially fill up the reaction chamber.

In some embodiments of aspects provided herein, in (d) the wafer is stationary during the dispending of the at least one reagent. In some embodiments of aspects provided herein, the method further comprises, after (d): (e) dispensing an inert gas into the reaction chamber. In some embodiments of aspects provided herein, in (e) the wafer is stationary during the dispensing of the inert gas. In some embodiments of aspects provided herein, the in (e) the wafer is spinning during the dispensing of the inert gas. In some embodiments of aspects provided herein, the method further comprises, after (d): adjusting the position of the wafer relative to a rotation axis of the vacuum chuck by a centering mechanism, thereby keeping the wafer rotating about a rotation axis of the vacuum chuck. In some embodiments of aspects provided herein, the method further comprises, after (d): opening the movable cover and removing the wafer from the vacuum chuck. In some embodiments of aspects provided herein, the method further comprises: controlling, by at least one processor, the placing in (a), the closing in (b), the adjusting any of the three or more adjustment pins in (c), the dispensing in (d), the adjusting the position of the wafer after (d), the opening the movable cover after (d), and the removing the wafer after (d). In some embodiments of aspects provided herein, the placing in (a) and the removing the wafer after (d) is done by a wafer conveyance robot. In some embodiments of aspects provided herein, the at least one processor synchronizes and repeats a plurality of times of the placing in (a), the closing in (b), the adjusting any of the three or more adjustment pins in (c), the dispensing in (d), the adjusting the position of the wafer after (d), the opening the movable cover after (d), and the removing the wafer after (d). In some embodiments of aspects provided herein, the method further comprises: creating a plurality of features on the wafer; detecting signals corresponding to each of the plurality of features on the wafer by fluorescence microscopic imaging; wherein the signals display a smaller variation when compared to signals generated from a corresponding wafer made in a flow cell. In some embodiments of aspects provided herein, the method further comprises: repeating (a), (b), (c), (d), and optionally, other steps described herein, thereby creating a plurality of oligonucleotides on different features of the wafer.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 is a perspective view of a wafer processing apparatus 100 as an embodiment of the present disclosure.

FIG. 2 depicts a partial perspective view of the reaction assembly 200 of a wafer processing apparatus as an embodiment of the present disclosure.

FIG. 3 shows a partial sectional view of the reaction assembly 300 of a wafer processing apparatus as an embodiment of the present disclosure.

FIG. 4 shows a view of a Spincell having the wafer processing apparatus enclosed as an embodiment of the present disclosure.

FIG. 5 shows a partial sectional view of the Spincell 500 as an embodiment of the present disclosure.

FIG. 6 shows a pick-and-place wafer handling robot transferring a wafer from the Spincell.

FIG. 7 shows a sample wafer with 7 chips from different locations which are sampled for HPLC analysis.

FIG. 8 shows a conventional flow cell for microarray synthesis demonstrating the flow direction of reagents added into the flow cell.

FIG. 9 shows the IPLC spectrum of DMT-10T synthesized by Spincell.

FIG. 10 shows the IPLC spectrum of Phoro-10T synthesized by Spincell.

FIG. 11 shows fluorescence microscopic image of patterns synthesized by flow cell.

FIG. 12 shows fluorescence microscopic image of patterns synthesized by Spincell.

FIG. 13A shows the fluorescence intensities of 21 chips from flow cell wafer.

FIG. 13B shows the fluorescence intensities of 21 chips from Spincell wafer.

FIG. 13C shows the comparison of average fluorescence intensities and variations of the chips from flow cell wafer and from Spincell wafer.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

DNA sequence microarrays or DNA chips have become a useful tool in biological and biomedical sciences to understand the correlation of gene sequences with their functions. In some cases, DNA chips containing surface-bound oligonucleotides or probes are used to interrogate target nucleic acid sequences via hybridization.

In general, microarray is a biochip which is printed with thousands to millions of micrometer-sized features on a solid substrate, with each feature having a plurality of designated biological probes (e.g. DNA sequences or peptides/proteins). Microarrays have revolutionized life sciences and biotechnology, providing scientists a high throughput screening tool for biomolecular detection and analysis at a very high efficiency. DNA microarrays have been widely used in analysis of gene expression, single nucleotide polymorphisms (SNP) genotyping and genomics sequencing. Microarray has been successfully commercialized.

Current methods to fabricate deoxyribonucleic acid (DNA) microarray include spot DNA onto nylon membranes or glass slides by robots with pins or ink jet printers. This usually involves naturally available DNA molecules or fragments thereof. When the require DNA sequences are not naturally available, oligonucleotides may be synthesized de novo on the solid surface of the array in a controlled manner. A system, device and method to synthesize non-natural or natural DNA sequences on DNA chips that are easy to manufacture with high fidelity in synthesized DNA probes on the surface are desirable. Accordingly, new system and methods to allow controlled chemical synthesis on a solid surface are of interest in the biomedical and biopharmaceutical field.

Microarrays of de novo synthesized oligonucleotides offer a number of advantages over other types of DNA microarrays, including (i) more controlled specificity of hybridization, which makes them particularly useful for the analysis of single nucleotide polymorphisms or mutational analysis; (ii) versatility to address questions about transcriptome composition such as the presence and prevalence of alternatively spliced or alternatively polyadenylated transcripts; (iii) capacity to systematically screen whole genomic regions for gene discovery; and (iv) ability to generate sequence information independent of biological samples when manufacturing custom-made microarrays.

However, manufacturing custom-made oligonucleotides microarrays may require inert and controlled environment due to the presence of air- and/or moisture-sensitive reagents in oligonucleotide synthesis. Further, chemical synthesis on a solid surface may require the use of large quantity of such air- and/or moisture-sensitive reagents, which may increase the cost of the manufacture or prolong the average turnover time for the manufacture of wafers. Finally, because oligonucleotide synthesis requires the repetition of similar synthetic manipulations with different reagents, contamination by reagent leftovers may present a problem.

The power of microarray is limited by the number of features within the unit area on the substrate. Higher feature density may allow running larger scale parallel analysis within the same microarray and provide more comprehensive results that may extend the scope of microarray applications and enable scientists to explore new findings. Among the different methods to synthesize microarrays, including, for example, solid-contact pin printing, microstamping, inkjet printing, and photochemistry-based printing, the photochemistry-based printing may be the most practical for high-density microarray manufacturing. Photochemistry-based printing may be intrinsically parallel and scalable which may make it flexible in terms of materials management, manufacturing throughput, and quality control. The challenge of high-density microarray synthesis can be to realize the precise synthesis of biomolecules at defined small (e.g. <5 micrometer) features on the substrate.

In the photochemistry-based synthesis of microarrays, the substrate can be flooded with the fluidic reagent containing UV light sensitive molecules and the photo mask can be used to selectively activate/deactivate molecules at specific spots for the next layer/round of synthesis. For instance, to synthesize oligonucleotides, the reagents can be extremely volatile and not affinitive to the substrate, and the synthesis may require the use of a large volume of air- and/or moisture-sensitive reagents to flush the substrate to make sure that the entire surface can be covered by reagents so that the same chemistry occurs universally or substantially uniformly on different locations on the chip surface for each step. At present, the cost of reagent usage and the average turnover time for the manufacturing of microarrays may not be feasible or efficient and may be cost-inhibitive if to fulfil the requirements.

In addition, the traditional chemical synthesis in photochemistry-based printing uses “flow cell”, an apparatus that can trap and agitate the fluidic reagents in an O-ring sealed chamber (see, e.g., FIG. 8), to flood the substrate with reagents. However, flow cell method may be difficult to be standardized and fully automated into a manufacturing process due to its fundamentals. For example, the fragile wafer may have to be in heavy contacts on both sides with different pieces of the flow cell to seal and agitate the reagents. Further, the synthesis (of e.g. oligonucleotide) quality across the substrate using flow cell is not consistent or uniformed, because the agitation of reagents by bubbling inertia gas within the flow cell can be inherently an irregular mechanism. Thus, the challenges for the chemical synthesis in photochemistry-based printing remain in a) the cost of reagent usage, 2) the automation, and 3) the uniformity of the synthesis quality across the substrate. It is desirable for new system and methods to allow controlled chemical synthesis on a solid surface, especially for the photochemistry-based synthesis of microarrays, in the biomedical and biopharmaceutical field.

After much effort in experimentation, Applicants have developed a system and method to synthesize chemical entities on a substrate to resolve the above difficulties, named as “Spincell” in this disclosure. Spincell may use the spin coating process, which can be automated by robotics pick and place (PnP) solutions in a fully automated manufacturing process. Specifically, Spincell can trap and agitate a small volume of fluidic reagent to soak or cover the entire surface of the substrate, so that the synthesis only require a reduced volume of reagent, when compared with the traditional flow cell systems. In other words, the amount and cost of reagent usage can be reduced. Besides, due to its symmetric mechanics, Spincell can improve the uniformity of the synthesis quality across the substrate. For example, using Spincell along with photolithography, we may fabricate high-density DNA microarrays having, for example, 3 micrometer sized features.

Additionally, Spincell can be used in other fluidic-based chemical syntheses on flat substrates. For example, other fluidic-based chemical syntheses may have similar challenges in the cost of reagent usage, the automation and the quality assurance, including, for example, in the manufacturing of protein microarray and microfluidic chip.

As used herein, the singular forms “a”, “an”, and “the” include plural references unless the context clearly dictates otherwise.

The term “fragment” as used herein generally refers to a fraction of the original DNA sequence or RNA sequence of the particular region.

The term “nucleotide,” as used herein, generally refers a molecule that can serve as the monomer, or subunit, of a nucleic acid, such as deoxyribonucleic acid (DNA) or ribonucleic acid RNA). A nucleotide can be a deoxynucleotide triphosphate (dNTP) or an analog thereof, e.g., a molecule having a plurality of phosphates in a phosphate chain, such as 2, 3, 4, 5, 6, 7, 8, 9, or 10 phosphates. A nucleotide can generally include adenosine (A), cytosine (C), guanine (G), thymine (T) and uracil (U), or variants thereof. A nucleotide can include any subunit that can be incorporated into a growing nucleic acid strand. Such subunit can be an A, C, G, T, or U, or any other subunit that is specific to one or more complementary A, C, G, T or U, or complementary to a purine (i.e., A or G, or variant thereof) or a pyrimidine (i.e., C, T or U, or variant thereof). A subunit can enable individual nucleic acid bases or groups of bases (e.g., AA, TA, AT, GC, CG, CT, TC, GT, TG, AC, CA, or uracil-counterparts thereof) to be resolved. A nucleotide may be labeled or unlabeled. A labeled nucleotide may yield a detectable signal, such as an optical, electrostatic or electrochemical signal.

The term “about” or “nearly” as used herein generally refers to within +/−15%, 10%, 9%, 8%, 7%, 6%, 5%, 4%, 3%, 2%, or 1% of the designated amount.

All words of approximation as used herein should be construed to mean “approximate,” rather than “perfect,” and may accordingly be employed as a meaningful modifier to any other word, specified parameter, quantity, quality, or concept. Words of approximation, include, yet are not limited to terms such as “substantial”, “nearly”, “almost”, “about”, “generally”, “largely”, “essentially”, “substantially”, “closely approximate”, etc. For example, the term “substantially” includes “reasonably close to: nearly, almost, about”, connoting a term of approximation known to a person skilled in the art.

As used herein, the terms “polynucleotide”, “oligonucleotide”, “nucleotide”, “nucleic acid” and “nucleic acid molecule” generally refer to a polymeric form of nucleotides (polynucleotides) of various lengths, either ribonucleotides (RNA) or deoxyribonucleotides (DNA). Examples of nucleotide sequences are sequences corresponding to natural or synthetic RNA or DNA including genomic DNA and messenger RNA. The length of the sequence can be any length that can be amplified into nucleic acid amplification products, or amplicons, for example, up to about 20, 50, 100, 200, 300, 400, 500, 600, 700, 800, 1,000, 1,200, 1,500, 2,000, 5,000, 10,000 or more than 10,000 nucleotides in length, or at least about 20, 50, 100, 200, 300, 400, 500, 600, 700, 800, 1,000, 1,200, 1,500, 2,000, 5,000, 10,000 or 10,000 nucleotides in length.

The term “array” as used herein, when describing a device, a system, sensors, sample chambers, etc., generally refers to a one-dimensional or two-dimensional set of microstructures. An array may be any shape. For example, an array may be a series of microstructures arranged in a line, such as the array of squares. An array may be arranged in a square or rectangular grid. There may be sections of the array that are separated from other sections of the array by spaces. An array may have other shapes. For example, an array may be a series of microstructures arranged in a series of concentric circles, in a series of concentric squares, a series of concentric triangles, a series of curves, etc. The spacing between sections of an array or between microstructures in any array may be regular or may be different between particular sections or between particular pairs of microstructures. The microstructure arrays of the present disclosure may be comprised of microstructures having zero-dimensional, one-dimensional or two-dimensional shapes. The microstructures having two-dimensional shapes may have shapes such as squares, rectangles, circles, parallelograms, pentagons, hexagons, irregular shapes, etc.

The terms “plate” and “substrate” as used herein generally refer to the solid portion of an apparatus whose surface is used to synthesize oligonucleotides or conduct chemical reactions.

A characteristic of a “thin-film,” as disclosed herein generally refers to that a layer of mobile phase, solution or liquid is spread over a surface of a plate through the action of surface tension, and/or adhesion to the surface of the plate. Preferably, a thin film is a liquid sample in which the diffusion time is no more than about four-fold greater, more preferably no more than about three-fold greater, more preferably no more than about two-fold greater, more preferably no more than about one-fold greater in one dimension than that in any other dimension. Preferably, the temperature conductance characteristics of a thin film sample are no more than about four-fold greater, more preferably no more than about three-fold greater, more preferably no more than about two-fold greater, even more preferably no more than about one-fold greater in one dimension than that in any other dimension.

The term “processor” as used herein generally refers to a personal computer with associated memory. The processor would have sufficient transient RAM memory, non-transient storage memory, processing power, and hardware, such as interface cards to run the associated control software, interface with and operate the automated components of the apparatus, such as the various pumps, motors, valves, sensors, and detectors, and record the values from the sensors, probes and detectors.

The term “wafer” as used herein generally refers to a plate, substrate, or semiconductor chip. The wafer may be circular. The diameter of a wafer can be, for example, about 50 mm, about 100 mm, about 150 mm, about 200 mm, about 250 mm, or other lengths. In addition, the wafer may comprise a layer of SiO₂ on its surface. The thickness of the SiO₂ layer may be about 20 nm, about 30 nm, about 40 nm, about 50 nm, about 55 nm, about 60 nm, about 65 nm, about 70 nm, about 75 nm, about 80 nm, about 100 nm, and more than 100 nm. The wafer may comprise an organic polymer layer on its surface. The wafer may comprise surface hydroxyl groups for attachment or reactions.

The term “carboxyl derivative” as used herein generally refers to functional groups that comprise acyl group and can form ester or amide bonds with another reagent comprising hydroxyl or amino groups. Examples of carboxyl derivative include carboxylic acid, acyl halide, anhydride, ester, thioester, and acyl phosphate.

The term “phosphorylating reagent” as used herein generally refers to a chemical reagent or a mixture of chemical reagents that are capable of introducing a phosphate group or a phosphite group into another molecule. An example of a phosphorylating reagent is a phosphoramidite reagent, which can react with a nucleoside monomer or oligonucleotide that comprises a hydroxyl group to give a phosphorous acid trimester what is subsequently oxidized to a phosphoric acid trimester of the nucleoside monomer or oligonucleotide.

The term “flow cell” as used herein generally refers to a reaction chamber that contains chemical entities immobilized to a solid support, to which chemical reagents are iteratively applied and washed away such that the incoming chemical reagents react with the immobilized chemical entities on the solid support.

Devices and Methods

The present disclosure provides methods, devices, and systems to enable fabrication of an array of oligonucleotide or other organic molecules on the surface of a plate. The methods, device, and systems of the present disclosure can comprise components including, but not limited to:
1. Spincell, which comprises an upper portion having a cover and a lower portion. The Spincell can enclose, under the cover, a wafer, a vacuum chuck, a lid and a reaction chamber. The cover connects with and engages the lid. The cover can be transparent. The cover can move upward or downward relative to the wafer and vacuum chuck to enclose or expose the wafer, the lid and the vacuum chuck for operations. The Spincell can communicate with and engage with other devices, such as, for example, robot mechanisms transferring the wafer, and/or other fluidic device to deliver reagents, solutions and/or gases to the reaction chamber, or apply or break the vacuum surrounding the reaction chamber.
2. Wafer cassette, which can hold a plurality of wafers. Wafers can be placed into and out of the wafer cassette.
3. Wafer conveyance robot, which can retrieve a specific wafer from a first wafer cassette, transfer the wafer to at least one pre-determined location; and place the wafer to a second wafer cassette or the first wafer, depending on the needs. The wafer conveyance robot may comprise at least one motor, at least one movable arm, and a wafer holder attached to the end of one arm. The wafer conveyance robot can move horizontally and vertically with the help of the motor(s).
4. Vacuum chuck, which can be a vacuum suction type to secure a wafer during the chemical synthesis. It may comprise no side arms. It may comprise at least two side arms, at least three side arms, or at least four side arms to facilitate the positioning of the wafer on top of the vacuum chuck. The vacuum chuck is not limited as long as the chuck can vacuum-suck and hold an object to be sucked and held via a mechanism of a vacuum pump.
5. Lid, which can be raised or lowered to a desired height manually or by a motor. The lid may have at least one supporting column connected to either the motor or an arm controlled by the motor. The at least one supporting column may be adjusted manually or mechanically so that the lid can adopt selected positions relative to the wafer lying below. The lid may be in a disk shape. The bottom face of the lid may be facing the top surface of the wafer on the vacuum chuck and may substantially cover the top surface of the wafer when the lid is lowered. The lid may align with the wafer along a vertical axis at the center of and perpendicular to the surface of the wafer. In the middle of the lid is a nozzle for controlled delivery of solutions or reagents to the top surface of the wafer. The reagents may be in solution, liquid or gas forms. The delivery of solutions/reagents may be facilitated by compressed air or a pump. The amount and sequence of solutions/reagents to be delivery as well as the rate of delivery may be controlled by an external controller, for example, a computer or a microprocessor. The wafer processing apparatus can further comprise a plurality of containers for holding the solutions/reagents, wherein the nozzle is in flow communication and operatively associated with each container such that the nozzle can selectively and sequentially dispense an amount of a reagent/solution. The solutions/reagents can be transferred to the nozzle via a conduit or tube on top of the lid. The nozzle can blow a gas (i.e., air, nitrogen, other inert gases, or a mixture of inert gases) in-between the lid and the top surface of the substrate, thereby, removing excess reagents remaining on the surface of the substrate by pushing the reagents off the edge of the substrate, drying the top surface and/or separating the bottom surface of the lid from the top surface of the substrate. The diameter of the lid may be about the diameter of the wafer it covers, longer than the diameter of the wafer, or shorter than the diameter of the wafer.
6. Reaction chamber, which is the space between the lower surface of the lid and the top surface of the wafer, or the space of the “gap”. The term “gap” as used herein generally refers to the substantially cylindrical space enclosed by the lower surface of the lid, the top surface of the wafer, and an imaginary curved side defined by the circumferences of the lower surface of the lid and the top surface of the wafer. The gap distance is the vertical distance between the bottom surface of the lid and the top surface of the wafer. The gap distance can be controlled by adjusting the at least one supporting column and the gap distance may range from about 20 μm to about 2.0 mm. The gap distance may be about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 160 μm, about 170 μm, about 180 μm, about 190 μm, about 200 μm, about 210 μm, about 220 μm, about 230 μm, about 240 μm, about 250 μm, about 260 μm, about 270 μm, about 280 μm, about 290 μm, about 300 μm, about 400 μm, about 500 μm, about 600 μm, about 700 μm, about 800 μm, about 900 μm, about 1 mm, about 1.1 mm, about 1.2 mm, about 1.3 mm, about 1.4 mm, about 1.5 mm, about 1.6 mm, about 1.7 mm, about 1.8 mm, about 1.9 mm, about 2.0 mm.

The reaction chamber may be semi-enclosed due to the small gap distance between the two aforementioned surfaces. The gap distance can be controlled to allow the spreading and mixing of a solution delivered via the nozzle in the lid. For example, if the gap distance is too large, solutions/reagents dispersed on the surface of the wafer may flow off the surface due to the gravity of the solutions/reagents. On the other hand, if the gap distance is too small, there may not be enough volume for the surface reactions to occur or may slow down the speed of the spread of the reagents/solutions. The concentrations of the reagents dispersed can be varied according to the volume of the reaction chamber chosen. The reaction chamber can comprise an aqueous or organic environment in which a plurality of reagents introduced from the nozzle may be present. The plurality of reagents may react with each other or react with intermediate products formed by previous reactions. For example, a reagent newly delivered onto the surface of the wafer may react with functional groups attached to the surface of the wafer. A reagent newly delivered may react with previously delivered reagent(s) staying on the surface of the wafer.

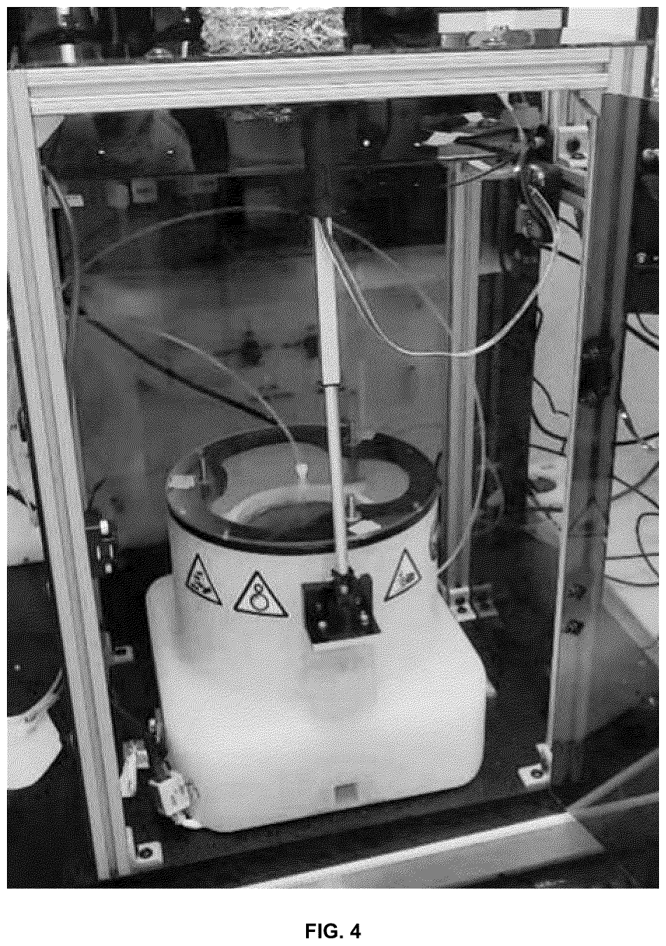

In one embodiment, a Spincell is shown in FIG. 4. The Spincell is shown in the closed mode enclosing the wafer, the lid, and the vacuum chuck. The Spincell can comprise a cover (e.g., a transparent plate), and a programmable spin coater with various components and modules to perform the chemical synthesis for the photochemistry-based microarray manufacturing. A computer device or a processor can communicate with the Spincell via an ethernet or wireless connection to control the spin speed, direction, amplitude, period, chuck vacuum and other features of the spin coater. The computer device or processor can be placed in the lower portion of the Spincell or can be external to the Spincell.

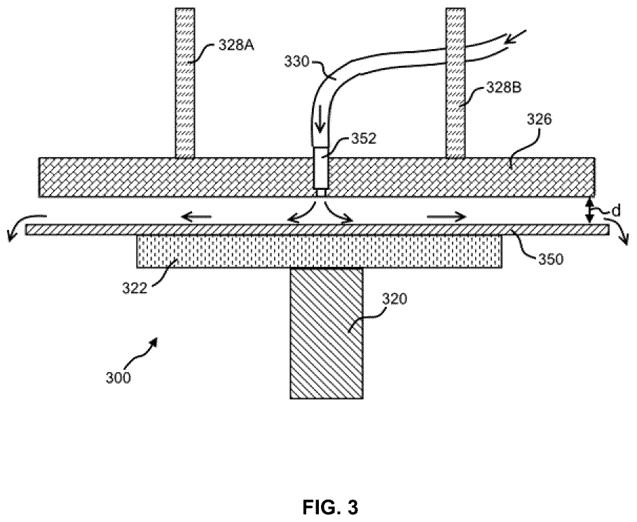

In one embodiment, a 6-inch wafer can be placed on a wafer chuck (also known as “vacuum chuck”) equipped with a centering mechanism (enclosed together with the wafer under the cover, not shown) to keep the wafer constrained at the center of rotation such that the center of the wafer aligns with the center of the wafer chuck or the axis of the rotating chuck (also known as supporting shaft). A round-shape transparent lid (e.g., a glass plate) may be conjugated with three or more micrometer-adjustment pins (also known as “supporting columns”) within a customized fixture that can be tightly installed on the top of the spin coater lid (e.g., Spincell cover or part of the Spincell cover). Accordingly, when the upper lid is fully closed onto the lower bowl (also known as the “base” or part of the base) of the spin coater (e.g., as shown in FIG. 4), the transparent lid (e.g. a glass plate) directly over the wafer can be positioned right above the wafer. In some embodiments, as shown in FIG. 3, the transparent lid (e.g., glass plate 326) can be slightly smaller in its diameter than that of the wafer to avoid the conflicts with the centering wires of the centering mechanism for centering purposes. By turning the adjustment pins (“supporting columns”) of the three or more micrometer-adjustment pins, the transparent lid (e.g., glass plate) can be tuned to be parallel to the surface of the wafer within a small (e.g., from about 200 micrometer to about 20 micrometer) distance from the surface of the wafer, thereby creating the reaction chamber for the chemical synthesis on the wafer surface.

In this way, as shown in FIG. 3, the small gap between the transparent lid (e.g., glass plate 326) and the wafer (e.g., 350) can form a “reaction chamber” for the chemical synthesis. A fluidic system can dispense the reagent into the gap or reaction chamber via a small inlet port (352) at the center of the glass plate (326). The width (d) of the gap or reaction chamber can be so small that the fluidic capillary force can trap and enable the reagent to fill the gap or reaction chamber, without flowing away, to fully soak the entire area of the wafer surface, allowing chemistry to take place essentially or substantially uniformly across the wafer. After the gap or reaction chamber is filled up with the reagent, the wafer can be spun at a low speed (e.g., about 100 round per minute or rpm) to agitate the reagent to facilitate the chemical reaction. To clean the wafer, solvent like acetonitrile (ACN) can be dispensed into the gap or reaction chamber to wash away the previous reagent. To dry the wafer, gases such as nitrogen and argon can be blown into the gap or reaction chamber from the inlet port (352) while the wafer was being spun at a high speed (e.g. 1000 rpm) to spin off the solvent residual.

In some embodiments, a linear actuator module (shown in FIG. 4) can control to open/close the spin coater lid (Spincell cover) for loading/unloading the wafer. The software in the computer or processor can synchronize the fluidic system, the spin coater and the linear actuator to repeat the above procedures with different reagents to implement the synthesis of a designated sequence of A, T, G, and C oligonucleotides on a wafer. Meanwhile, a pick and place (PnP) wafer handling robot (shown in FIG. 6) can be used to back and forth transfer the wafer, for example, between the Spincell and the mask aligner machine for photolithography, to automate the entire process (FIG. 6).

In addition, the computer device can control, for example, the delivery of the reagents, the movement of parts of the device, and other operation of the device.

The components of the apparatus can be made from stainless steel, aluminum, non-ferrous alloys, Teflon®, high density poly ethylene (HDPE), or any other material understood by those of ordinary skill in the art for use in particular applications that may depend on the solution acidity or alkalinity, salinity, temperature, or other chemical or physical properties, as well as the ability to prevent contamination and be properly cleaned between chemical reactions.

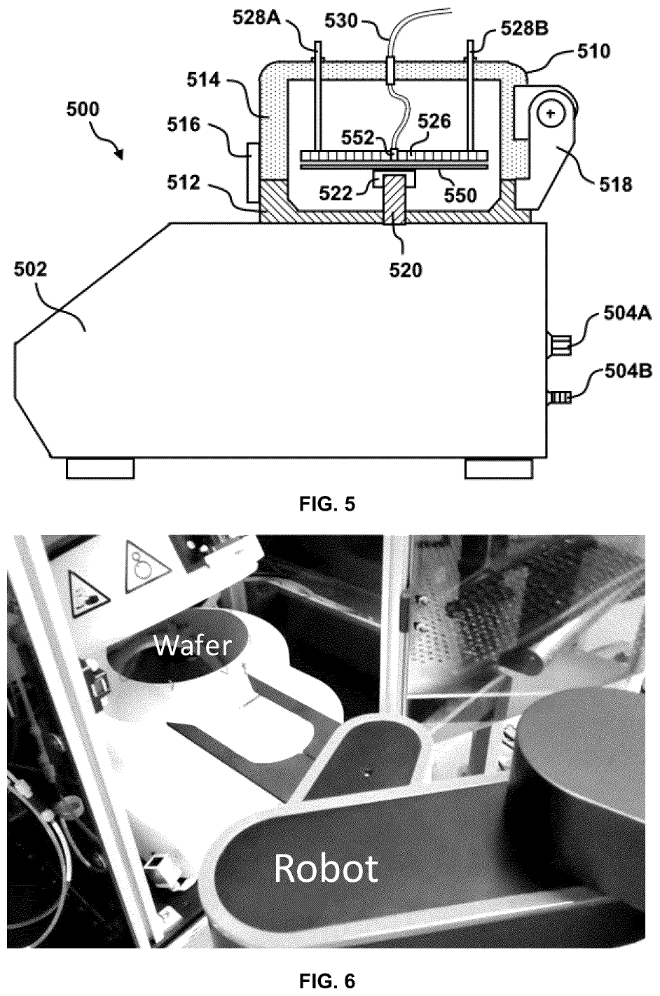

Referring to FIG. 5, the relative layout of the lid and the cover of the Spincell is further depicted as Spincell 500 according to another embodiment of the present disclosure. The Spincell 500 comprise a lower portion 502 and an upper portion 510. The lower portion 502 comprises adapters, for example, adapters 504 A and 504B, for connecting to power source, communication lines (wired or wireless), vacuum source, etc. The lower portion 502 also comprises parts that control the operation of the Spincell, including for example, motion control, communication control, programming control, and more. The motion control can regulate various motions of the Spincell, including, for example, the opening and closing of the cover of the Spincell, the spin operations of the vacuum chuck, the locking of the cover of the Spincell, the operation of the vacuum applied, the raise and fall the lid relative to the wafer, and more. The communication control regulates the internal communications between different components of the Spincell and the external communication with other devices and the operator via an input keyboard or touchscreen, for example. The programming control works together with other components of the Spincell to regulate the steps required to process the wafer, including, for example, the time length of each step, the speed of the vacuum chuck at various points of the process, the timing and amount of the reagents applied to the wafer, etc.

The upper portion 510 comprising a bowl 512 disposed on top of and affixed to the lower portion 510, a cover 514 controlled by a hinge or actuator 518 that raises and lowers the cover 514 relative to the bowl 512, a lock 516 that locks and unlocks the cover 514 relative to the base. The upper portion 510 also comprises a lid 526 with a nozzle 552 for controlled delivery of reagents to the top surface of a wafer 550, which is supported and secured by a vacuum chuck 520. The lid 526 is movable with the help of supporting columns 528A and 528B vertically. The supporting columns 528A and 528B engage with the cover 514 such that when the cover 514 is raised or lowered, the lid 526 is raise or lowered together with the cover 514. The vacuum chuck 520 may sit on and controlled by a supporting shaft 520.

The reagents can be transferred to the nozzle 552 via a conduit or tube 530 on the top of the lid 526 when the wafer 550 does not spin or when the wafer 550 remains stationary relative to the lid 526. The conduit or tube 530 can transfer gas, liquid or solution at a predetermined rate and in a predetermined amount. The conduit or tube 530 may be washed or gas dried in-between different deliveries of reagents so that contamination of reagents within the conduit or tube 530 is minimized. The delivery of reagents may be air-propelled or pump-controlled. The amount and sequence of reagents to be delivery as well as the rate of delivery may be controlled by an external controller, for example, a computer or a microprocessor, or the programming control of the Spincell.

When gas is used to deliver the reagents, the gas may be inert gas, such as, for example, nitrogen, argon or other noble gas, or mixture thereof. Other added advantages of using inert gas to deliver reagents may include drying of the conduit or tube 530 between deliveries using the passage of inert gas; protection of air- or moisture-sensitive reagents during delivery; maintaining a positive pressure of inert gas over the top surface of the wafer 550 during chemical synthesis; and removing excess reagents from the surface of the wafer 550 at the end of the chemical reactions, either by evaporation or by pushing the reagents over the edge of the wafer 550. When gas purges over the surface of the wafer 550, the wafer 550 does not spin or the wafer 550 can remain stationary relative to the lid 526.

When the lid 526 is lowered, the gap distance between the bottom surface of the lid 526 and the top surface of the wafer 550 can be controlled. The gap distance d between the top surface of the wafer 550 and the bottom surface of the lid 526 may range from about 20 μm to about 2 mm. The diameter of the lid 526 may be the same as the diameter of the wafer 550 it covers, longer than the diameter of the wafer 550, or shorter than the diameter of the wafer 550. In some cases, the diameter of the lid 526 is longer than the diameter of the wafer 550. The diameter of the wafer 550 can be, for example, about 50 mm, about 100 mm, about 150 mm, about 200 mm, about 250 mm, or other lengths.

Reagents in the forms of gas, liquid or solution may be introduced into the conduit or tube 530 in a controlled manner. The nozzle 552 may deliver the reagents onto the top surface of the wafer 550 when the wafer 550 does not spin or when the wafer 550 is stationary relative to the lid 526. Liquid reagents may spread by capillary action or surface tension when the wafer 550 does not spin or when the wafer 550 is stationary relative to the lid 526. The amount of reagents delivered can be calculated or estimated based on the volume of the reaction chamber or the volume of the gap, each of which may depends on the gap distance. After the reaction chamber has been filled with a first solution/reagent, the wafer 550 may remain stationary for at least 30 seconds, at least 40 seconds, at least 50 seconds, at least 60 seconds, at least 70 seconds, at least 80 second, at least 90 seconds, at least 100 seconds, at least 120 seconds, at least 3 minutes, at least 4 minutes, at least 5 minutes, or longer, to allow the solution/reagent to react with each other or other products formed previously in the reaction chamber before the start of the next delivery of a second solution/reagent. The delivered solution/reagent may form a substantially flat surface, e.g., forming a thin-film. In some cases, the solution delivered may comprise one reagent. In other cases, the solution delivered may comprise at least two reagents. In some cases, the solution delivered is a cleaning solution to wash away previous reagent, unreacted reagents or by-products remained in the conduit or tube 530 or remained on top of the wafer 550 or inside the reaction chamber.

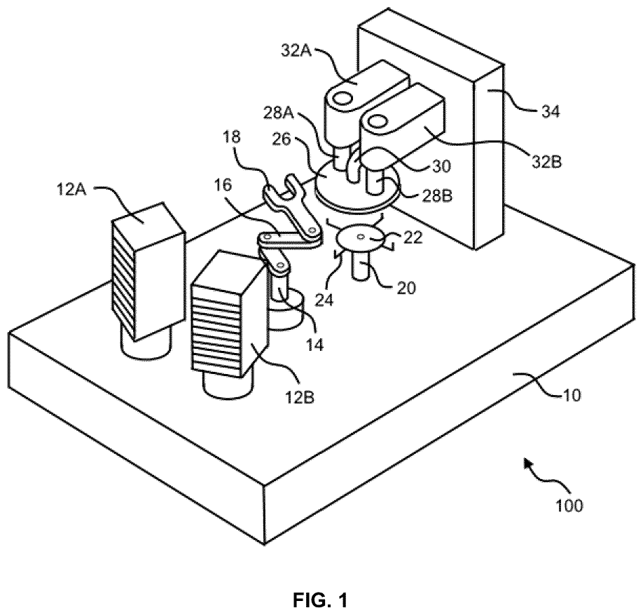

As shown in FIG. 6, the cover of the Spincell can be raised to allow the transfer-in and transfer-out of the wafer onto and away from the vacuum chuck. In some cases, as shown in FIG. 6, a pick and place (PnP) wafer handling robot can transfer the wafer between the Spincell and the mask aligner machine for photolithography to automate the entire process (e.g., FIGS. 1 and 6). Even though in one embodiment the wafer conveyance robot 16 in FIG. 1 is shown as stationary, a mobile wafer conveyance robot 16 can be used as well in other embodiments to perform the same task of transferring the wafer from one place to another. In some cases, multiple wafer conveyance robots can be used in the process disclosed herein.

Photolithography

To synthesize high-density DNA microarray, a commercial mask aligner (e.g., NxQ8000, Neutronix Quintel, CA) having the auto load and auto alignment functions can be used for photolithography in this work. This aligner can provide alignment accuracies of less than 0.5 micrometer 3 sigma. A group of patterned 7-inch masks having 3 micrometer features can be used to activate the designated spots on the wafer for the next layer of oligonucleotide synthesis. The light source can be 367 nm ultraviolet (UV), and the dose can be set at about 1500 mJ/cm² for each exposure.

After each synthesis cycle by Spincell, the wafer was transferred to the mask aligner for photolithography, and after the photolithography the wafer was returned to Spincell for the next synthesis cycle. By repeating these steps, different sequences of A, T, G and C oligonucleotides can be synthesized at different spots on the wafer. Following the complete synthesis, the wafer was sent for dicing to make individual microarray using the automatic dicing saw (DAD3240, DISCO, Japan). Each 6-inch wafer can be designed to contain about 244 microarrays, and each microarray can be in about 7.5 mm×7.5 mm size. After dicing, the individual microarray can be harvested for the subsequent biochemistry analysis.

We may synthesize high-density DNA microarrays using Spincell as disclosed herein. Oligonucleotides may be synthesized on wafers, such as, for example, 6-inch silicon wafers. High performance liquid chromatography (HPLC) can be used to measure the synthesis yield when using Spincell. Fluorescence microscopic imaging along with hybridization tests may be used to inspect the micrometer-sized features in the synthesized microarrays.

Experiment: Synthesis Yield

The stepwise synthesis yield of amidite T was measured to evaluate the performance of chemical synthesis by Spincell disclosed herein using high performance liquid chromatography (HPLC). However, as a part of photochemistry synthesis, photolithography would affect the synthesis yield, so two types of amidite T (DMT-T and Photo-T) sequences were both synthesized to examine two different scenarios without (in DMT-T synthesis) and with photolithography (Photo-T synthesis), corresponding to basic solution chemistry-based and photochemistry-based chemical synthesis, respectively. In these synthesis, no pattern was applied on the wafer, and instead, universal synthesis took place across the wafer surface so that sufficient molecules can be collected for HPLC analysis.

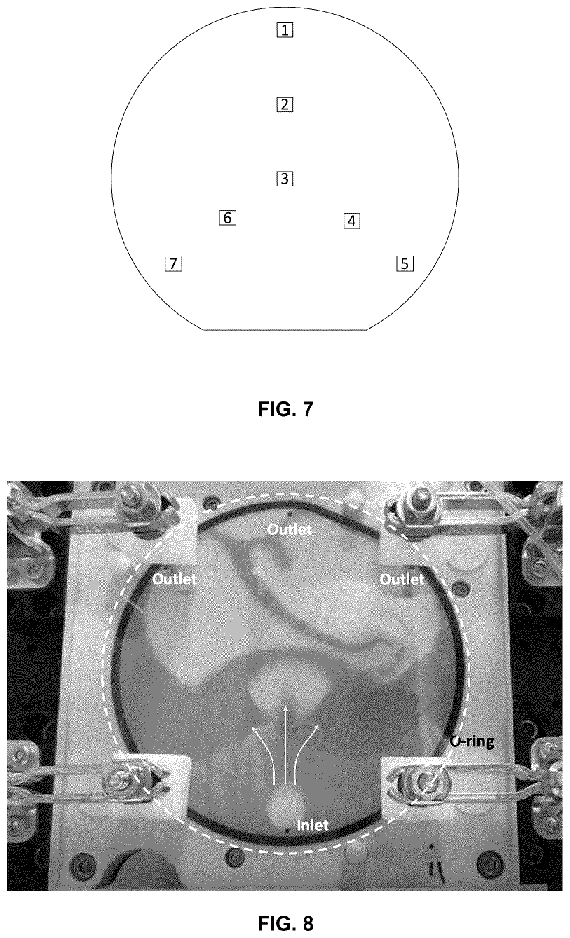

4,4′-Dimethoxytrityl (DMT) group is acid labile, and is used for protection of 5′-hydroxy group in nucleosides, particularly in oligonucleotide synthesis. DMT-T sequence was firstly synthesized to measure the yield, and in each cycle the synthesis went through 4 main steps—coupling, capping, oxidizing, and deblocking steps. The reaction periods for each of these 4 steps were 90 s, 30 s, 30 s, and 60 s respectively. Within the same synthesis cycle, the wash step by acetonitrile was applied between main steps to clean the previous chemical residuals to prepare for the next chemistry. DMT-T does not need photolithography to enable the continues synthesis, so the influence from photolithography did not skew the DMT-T synthesis yield results by Spincell. A sequence of 10 DMT-T (TTTTTTTTTT (SEQ ID NO:1)) was synthesized across the wafer, and the wafer was then diced into 244 chips with the dimension of 7.5 mm×7.5 mm. Synthesized molecules were cleaved off the chips located at 7 different positions (see FIG. 7) on the wafer to run the HPLC analysis to inspect if there would be yield differences across the surface.

Similarly, a sequence of 10 Photo amidite T was synthesized across the wafer as well. In specific, a crystal blank mask was used in photolithography to allow the photochemistry to take place all over the surface of the wafer without any patterning. Like DMT-T synthesis, chips from 7 different locations on the wafer were analyzed by HPLC to examine the yield variation over the surface. Different from DMT-T synthesis, a longer wash step including a drying action by argon was used at the end of each Photo-T cycle to clean the wafer before being transferred to the mask aligner for photolithography, and the synthesis was paused during the photolithography.

Experiment: Hybridization and Fluorescence Microscopic Imaging

In practice, designed probes in microarray hybridize the target DNA segments in the samples, and then the fluorescence microscopy is used to acquire images of microarrays. The imaging quality of microarray under fluorescence microscopy is critical for the following data acquisition, which directly determines the function of the microarray. Microarrays synthesized by Spincell were also tested with the hybridization and fluorescence microscopic imaging in this experiment. Other quality control(QC) steps can be taken to determine the accuracy and yields of the oligonucleotide synthesis and for trouble-shooting.

A standard AM1 sequence of “CGACATAGCCGACTTAGCAT (SEQ ID NO:2)” was synthesized using Spincell, and in photolithography a mask with 3 micrometer-sized features was used to print designated pattern for each layer of oligonucleotide synthesis. After the completed synthesis, the wafer was diced into 244 chips with the dimension of 7.5 mm×7.5 mm. In the synthesis, one mask was repeatedly used in each cycle, so the sequences in each 3-micrometer feature were the same, and all 244 microarrays were the same as well. Twenty-one out of 244 chips evenly or substantially evenly distributed across the wafer were selected to test with hybridization and fluorescence microscopic imaging (Keyence, BZ-X710, Japan) for QC purposes.

Experiment: Comparison Microarrays

For both the synthesis yield and fluorescence microscopic imaging analyses, microarrays were synthesized using the conventional flow cell approach for the purposes of comparisons with the developed Spincell. In conventional flow cell synthesis (FIG. 8), the reagent was injected into flow cell from the inlet at one end of the base of the flow cell to fill the lower half of the reaction chamber, which was then agitated by blowing argon bubbles into the reaction chamber to flush the wafer surface and ensure chemical reactions take place across the wafer surface. In our experiments, the chemistry and the reaction period for each individual step in the flow cell synthesis were kept the same as Spincell. The results of flow cell and Spincell microarrays were compared with each other. In FIG. 8, for the conventional flow cell approach for microarray synthesis; a crystal transparent quartz wafer (white dash line) was used to demonstrate the inside flow from the inlet (one at the lower portion of FIG. 8) to the outlets on the base of the flow cell (three at the upper portion of FIG. 8).

Results

flow cell required at least 6 mL reagent each time to enable the sufficient and complete chemical synthesis over the entire surface of the wafer, while Spincell only needed less than 2.5 mL volume when the gap was adjusted to be below 0.2 mm. The wafer can be loaded onto and unloaded from Spincell and then transferred to the mask aligner machine for photolithography using an automated wafer handling robot (see, e.g., FIG. 6).

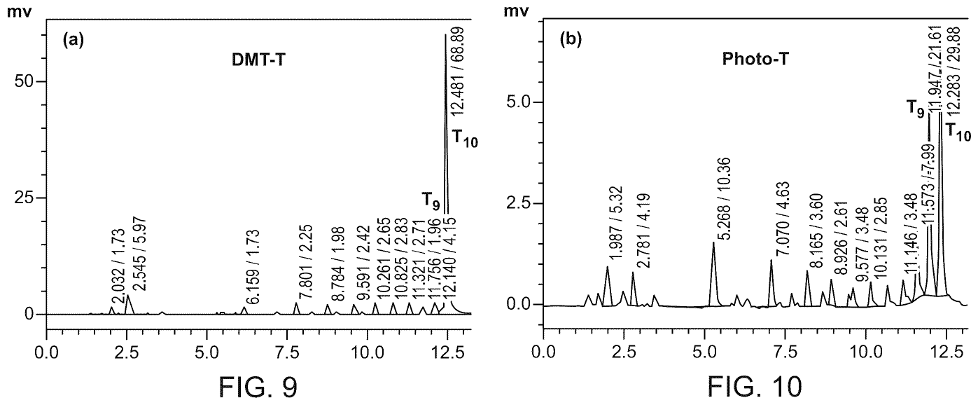

An example of HPLC spectra of DMT-T synthesis by Spincell is demonstrated in FIG. 9.

Both Spincell and flow cell microarrays provide clean spectra, clearly displaying the 10 peaks corresponding to the 1^{st} T, 2^{nd} T, . . . , 9^{th} T and 10^{th} T. The nominal synthesis efficiency (NSE) was calculated based on the below equation:

NSE=e^{\hat{ }}(ln(Y)/n)
NSE: Nominal Synthesis Efficiency
Y: Yield
n: Number of Steps

Over the 7 positions on the wafer, the average NSE of flow cell DMT-T microarrays is 95.69%, and Spincell DMT-T microarrays have an average NSE of 98.00%. The standard deviations for flow cell and Spincell groups are 1.00% and 0.98%, respectively. For DMT-T synthesis by Spincell, the representative HPLC spectra is illustrated in FIG. 9.

Since the photolithography cannot be an ideal chemistry process, the NSE of Photo-T synthesis is usually lower than the NSE of DMT-T synthesis for both flow cell and Spincell syntheses. For Photo-T synthesis, the representative HPLC spectra is illustrated in FIG. 10 (for the Spincell), with average NSEs of 92.6%+/−XX % and 90.1%+/−XX % for flow cell and Spincell synthesis, respectively.

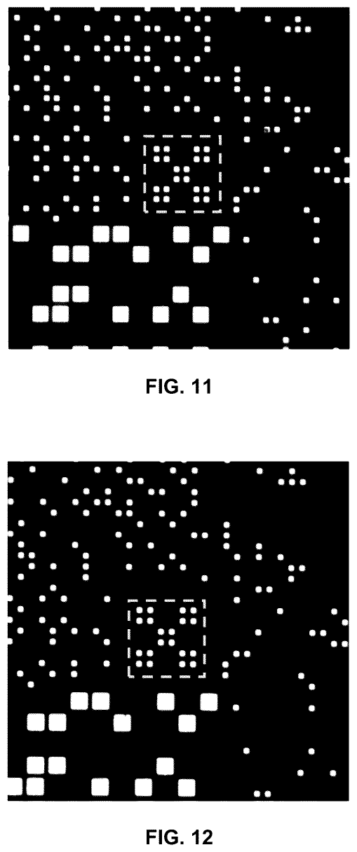

For AM1 sequence synthesis, both flow cell and Spincell microarrays obtained fluorescence images in good quality, presenting distinct 3 micrometer-sized square features with sharp edges under the fluorescence microscopy after hybridization process, see FIGS. 11A and 11B. Both flow cell (FIG. 11A) and Spincell (FIG. 11B) wafers obtained clear fluorescence microscopic images in good quality; the small white feature was 3 μm×3 μm square, and the big white feature was 8 μm×8 μm square; the images were taken from the same location for both wafers. The background noise was low in terms of the signal intensity of the feature, providing high signal-to-noise ratios. Within the same microarray, there were 5 images taken from randomly selected positions. In each image, a group of features in “X” were sampled (not shown), and the maximum intensities of the 6 features along the diagonal direction were measured. The average of the 6 maximum intensities was considered as the intensity of each image, and then the average intensity of the 5 images was calculated as the intensity of the individual microarray.

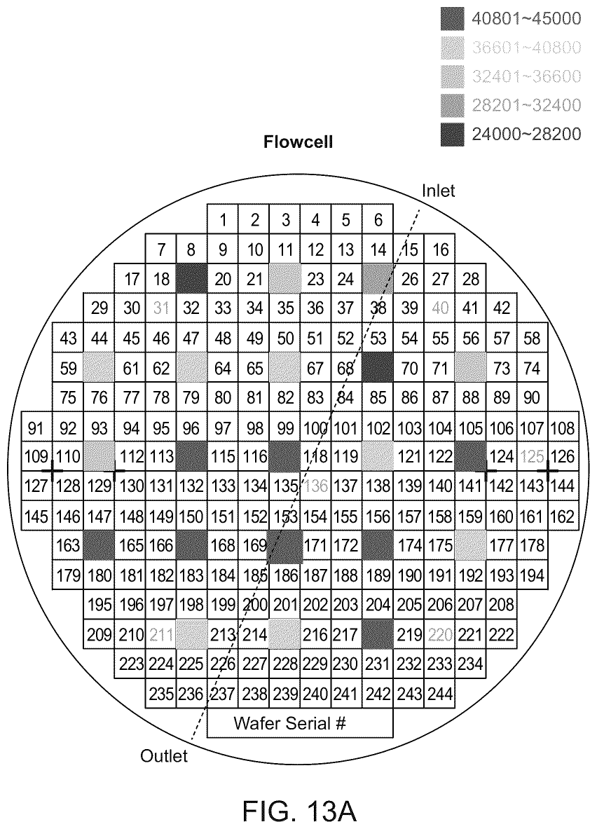

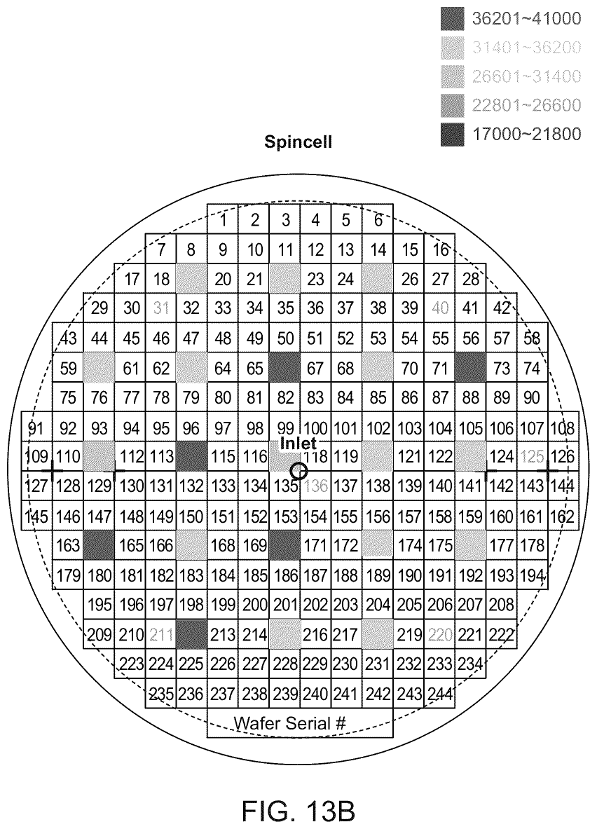

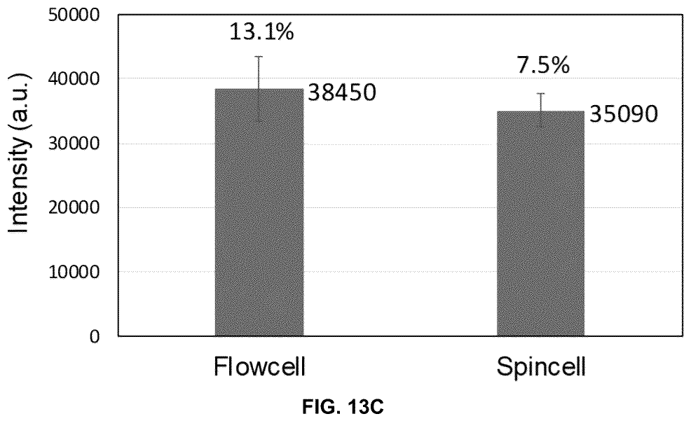

For both flow cell and Spincell wafers, intensities of 21 microarrays across the wafer were plotted in FIGS. 13A and 13B, and the average intensities of each microarray among the group of 21 microarrays were plotted in FIG. 13C. The flow cell wafer had an averaged intensity of 38450 a.u. with 13.1% variation, and the Spincell wafer had an averaged intensity of 35090 a.u. with 7.5% variation.

In FIGS. 13A-13C, the intensities of 21 chips from flow cell (FIG. 13A) and Spincell (FIG. 13B) wafers were plotted; dash line in (FIG. 13B) indicated the covered area by the glass plate (transparent lid). Over the entire wafer surface, flow cell wafer demonstrated a bigger variation than Spincell in terms of the fluorescence imaging intensities.

In this experiment, we demonstrated a system and method (Spincell) for chemical synthesis in photochemistry-based fabrication of high-density microarray, addressing the challenges in the cost of reagent usage and the automation of high-density microarray manufacturing process. Our results also indicated that the developed Spincell technology improved the quality variation of microarrays across the wafer.

In order to print or build high-density micrometer (and/or sub-micrometer) sized features into the microarray, photochemistry-based synthesis is the most practical solution comparing to other choices, such as the solid contact-pin printing and the inkjet printing. Although photolithography and its tools have been developed in semiconductor chips manufacturing, the challenges in high-density microarray fabrication still exist in the current chemical synthesis, which is yet costly and does not align with the automation methodology for high volume manufacturing. In addition, unlike the solid physics and chemistry in semiconductor chips which rely on simple chemistry and reagents (mostly inorganic chemistry techniques), the consistency of the biological molecules (e.g. DNA sequences using complex, organic chemistry) synthesis is difficult to be achieved in microarrays, and the quality of microarrays from the same wafer or same synthetic cycles usually varies.

In photochemistry-based synthesis of microarrays, the prerequisite is to ensure the chemical syntheses take place substantially uniformly to cover the entire surface of the wafer before and after the photolithography process. Unfortunately, the chemical synthesis of oligonucleotide is not friendly for manufacturing, in which each cycle of individual oligonucleotide synthesis includes a group of continuous solution-phase reactions with hazardous and volatile reagents, such as acetonitrile (ACN), tetrahydrofuran (THF), dichloromethane (DCM), etc. In addition, chemical reagents to synthesize oligonucleotides, including, for example, amidites, are extremely costly. Therefore, the amount (volume) of reagents needs to be limited, and meanwhile all fluidics must be controlled and isolated from the ambience during the synthesis process. Therefore, the two requirements of photochemistry-based synthesis of microarrays of oligonucleotides, i.e., uniform reaction efficiency for each step (more reagent is desired) and the high cost of reagents (less reagent is desired), seem to work against each other, when using the flow cell approach.

In current manufacturing, the flow cell idea for the chemical synthesis is to create a sealed reaction chamber on the surface of the wafer by tightly pressing the wafer against an O-ring (see the dashed line in FIG. 8), which lays in the same profile as the wafer and is half embedded on a flat base (see FIG. 8). Then the wafer, the O-ring and the base form a narrow chamber to trap a small volume of liquid reagents. There are a couple of inlet and outlet holes (see FIG. 8) machined on the base of the flow cell to inject and drain away the reagents. Inertia gas bubbles are blown into this chamber via the holes to agitate the fluid to enable the chemistry take place all over the surface. In synthesis, the flow cell is not fully filled and must be vertically positioned to allow the circulation of the fluid by gravity after being agitated by bubbles.

In flow cell, the synthesis was not well-distributed across the wafer. When placed vertically, the lower portion of the wafer can be immersed in the reagent, but the upper portion of the wafer can protrude above the reagent solution in the flow cell and can only be occasionally flushed by the reagent agitated by inertia gas bubbles. Thus, the degrees of synthesis in the lower portion and the upper portion of the same wafer can be quite different, which can explain the higher signals from microarrays in the lower portion than in the upper portion, a phenomena that can be observed under the fluorescence microscopic imaging for flow cell wafers. Accordingly, the quality consistency of microarrays from the same wafer cannot be assured when using the flow cell synthesis.

For large scale industrial manufacturing of microarrays, the chemical synthesis process can be able to be automated and assure the quality. In addition, the usage of reagents is also a concern, which directly determines the manufacturing cost. In Spincell, the hazardous and volatile reagent was maintained by the spontaneous capillary force within the narrow gap or reaction chamber, and unlike flow cell, neither hard contact nor load was applied to the wafer to constrain the fluidic during the process.

When trapped in he the gap or reaction chamber between the wafer and the glass plate (transparent lid), the reagent can be maintained (i.e., remained substantially stationary) by capillary force (liquid surface tension) rather than flow away, in contrast to the flow cell synthesis. Also, the size of this gap determines how much volume of reagent is needed to soak or cover the entire surface of the wafer. In physics, there is always a maximum value a for the width of the gap (distance between the wafer and the glass plate) to allow the capillary phenomena to happen, and for different liquids (reagents) against different surfaces, this maximum value a is not the same. However, for microarray manufacturing, the goal is to minimize the width of the gap to save the cost of reagent usage. In theory, the width of the gap can be infinitely close to zero, but, if so, the wafer may tightly stick to the glass plate, a phenomenon which cause the wafer becomes difficult to be released from the transparent lid after the synthesis step. Therefore, there is also a minimum value R for the width of the gap to allow a continuous manufacturing process.

The smaller the width of the gap is, the more sophisticated Spincell has to be, demanding lots of investment on the hardware building. Thus, the real practice may need to find a reasonable small width for an easy process in manufacturing, and the wafer can be freely loaded and unloaded from Spincell using wafer handling robots, which can be further integrated into a fully automated photochemistry-based synthesis process. For example, the width was set at less than 200 micrometer in this experiment, and the volume of reagent usage can be less than 2.5 mL each time to soak or cover the surface of the 6-inch wafer. Thus, the volume of reagent used is lower than (about 60% off) the >6 mL usage required in the current flow cell synthesis.

Although moisture can be harmful for the oligonucleotide synthesis and the reagent like acetonitrile is a strong solvent to attract moisture, the influence of moisture may not be a concern in Spincell. The reagent trapped in the gap or the reaction chamber (the space between the wafer and the glass plate) may form like a “disc” (at least in term of the shape) due to the capillary effect, and only the edge of the “disc” can be exposed to the ambience, but not the top and bottom surfaces of the “disk”. For instance, if the width of the gap was set at 200 micrometers, the area exposed to the ambience was only about 0.266% of the entire surface area of the 6-inch disc, which is almost negligible. In addition, Spincell itself can be an enclosure when the lid is fully closed during the synthesis, and Spincell can be also purged with dry nitrogen or argon or other inert gases to protect the chemical reactions from ambient moisture and oxygen, for example.

In Spincell, the reagent can substantially evenly spread over the entire surface of the wafer by capillary force, and the chemical reactions can take place substantially uniformly almost at the same time and for the same period in each synthetic step. Spinning the wafer to agitate the fluidic to facilitate the synthesis may introduce a little difference along the radius direction regarding the tangential speeds, but the Spincell synthesis can be consistent and center symmetric. Due to the above and other possible reasons, Spincell synthesis can provide a smaller variation of the microarray quality across the wafer than flow cell synthesis. For example, the experiment disclosed herein shows that the fluorescence microscopic imaging results confirm the same (Spincell standard deviation: 8% vs. flow cell standard deviation: 16%).

Photochemistry-based method enables the synthesis of extremely high-density microarrays, for example, more than 25 million features can be printed in a fingernail-sized microarray using the system and methods disclosed herein. Instead of the solid mask photolithography, tools such as digital micromirror device (DMD) can be used to project even smaller sub-micrometer features to microarrays. The progress is making microarrays more powerful than before. More new applications can be explored with these extremely high-density microarrays, such as high throughput parallel 2 dimensional/3 dimensional imaging of tissues, and high throughput DNA sequencing. The developed Spincell technology can address the urgent needs in a) the reagent cost saving, b) the automation of the process for large scale manufacturing, and c) the quality assurance for extremely high-density microarrays, making the delivery of large volumes of low-cost microarray products to the market possible.

In addition, as a physical platform, Spincell can be used in other liquid-based chemical syntheses on substrate as well, which have the similar cost, automation and quality challenges, for example protein biochips, and microfluidic devices

Methods, devices, and systems of the present disclosure can employ variants of the above components assembled together to create a system capable of manufacture wafers and conducting surface chemistry on the surface of the wafers.

General Methods

The present disclosure employs, unless otherwise indicated, conventional techniques in photolithography, chemical etching, general machining, microfluidics, organic chemistry, biochemistry, oligonucleotide synthesis and modification, nucleic acid hybridization, molecular biology, microbiology, genetic analysis, recombinant DNA, and related fields as are within the skill of the art. These techniques are described in the references cited herein and are fully explained in the literature. See, for example, Maniatis, Fritsch & Sambrook, MOLECULAR CLONING: A LABORATORY MANUAL, Cold Spring Harbor Laboratory Press (1982); Sambrook, Fritsch & Maniatis, MOLECULAR CLONING: A LABORATORY MANUAL, Second Edition, Cold Spring Harbor Laboratory Press (1989); Ausubel, et al., CURRENT PROTOCOLS IN MOLECULAR BIOLOGY, John Wiley & Sons (1987 and annual updates); Gait (ed.), OLIGONUCLEOTIDE SYNTHESIS: A PRACTICAL APPROACH, IRL Press (1984); Eckstein (ed.), OLIGONUCLEOTIDES AND ANALOGUES: A PRACTICAL APPROACH, IRL Press (1991); Birren et al. (eds.) GENOME ANALYSIS: A LABORATORY MANUAL, Cold Spring Harbor Laboratory Press, 1999.

In addition, this disclosure uses the systems and methods disclosed in U.S. PG. Pub. Nos. US20170001165 and US20200070119, each of which is entirely incorporated herein by reference.

### EXAMPLES

Notwithstanding the disclosure above, some of the embodiments of the system and method of a wafer processing apparatus according to the present disclosure will be described below with reference to the drawings.

FIG. 1 is a perspective diagram showing the general structures of a wafer processing apparatus 100 according to a first embodiment of the present disclosure. In FIG. 1, a wafer conveyance robot 16 may compose a first robot mechanism 14 and a wafer holder 18. The wafer conveyance robot 16 may be on a polar coordinate system and disposed on an upper surface of a base 10. Wafer cassettes 12A and 12B, and a vacuum chuck 22 may be disposed radially around the wafer conveyance robot 16. The wafer cassettes 12A and 12B, and the vacuum chuck 22 may be arranged within a range in which a wafer can be brought into and out of the wafer cassettes 12A and 12B by the wafer conveyance robot 16, and placed on the top of the vacuum chuck 22. Even though in this embodiment the wafer conveyance robot 16 in FIG. 1 is shown as stationary, a mobile wafer conveyance robot 16 can be used as well in other embodiments to perform the same task of transferring the wafer from one place to another. In some cases, multiple wafer conveyance robots can be used in the process disclosed herein.

In some embodiments, the wafer cassettes 12A and 12B may accommodate a plurality of wafers before and after wafer processing. The first robot mechanism 14 can move vertically and horizontally so that a wafer can be brought into and out of the wafer cassettes 12A and 12B by the wafer conveyance robot 16, and be placed on the top of the vacuum chuck 22. The vacuum chuck 22 may comprise side arms 24 so that when a wafer is placed on top of the vacuum chuck 22 by the wafer holder 18, the wafer may be centered on the vacuum chuck 22. A vacuum applied via the vacuum chuck 22 may hold the wafer in place and force the wafer move together with the moving vacuum chuck 22. The vacuum chuck 22 may be positioned on top of a supporting shaft 20. The supporting shaft may optionally move vertically to adjust the height of the wafer.

In some embodiments, directly above the vacuum chuck 22 is a lid 26. The lid 26 may be in a flat disk shape. The bottom surface of the lid 26 may face the top surface of the wafer on the vacuum chuck 22 and may substantially cover the top surface of the wafer when the lid 26 is lowered into the position for conducting chemical synthesis. In some cases, the lid 26 may align with the wafer along a vertical axis at the center of and perpendicular to the surface of the wafer. The wafer may be circular. In some cases, there may be two supporting columns 28A and 28B holding the lid 26. In other cases, more than two supporting columns 28 may hold the lid 26. The two supporting columns 28A and 28B may be connected with a wall portion 34 via side arms 32A and 32B, respectively. The side arms 32A and 32B can move vertically and/or horizontally with the help of robot(s)/motor(s).

In some embodiments, the operation of the wafer processing apparatus may start with the removal of one wafer from the wafer cassette 12A by the wafer conveyance robot 16 via the wafer holder 18. Then the wafer conveyance robot 16 may place the wafer on top of the vacuum chuck 22. Vacuum may be applied to the bottom surface of the wafer which may be suction-adhered to the vacuum chuck 22. After the wafer is secured on the vacuum chuck, steps to conduct chemical synthesis on the top surface of the wafer may start in the reaction chamber.

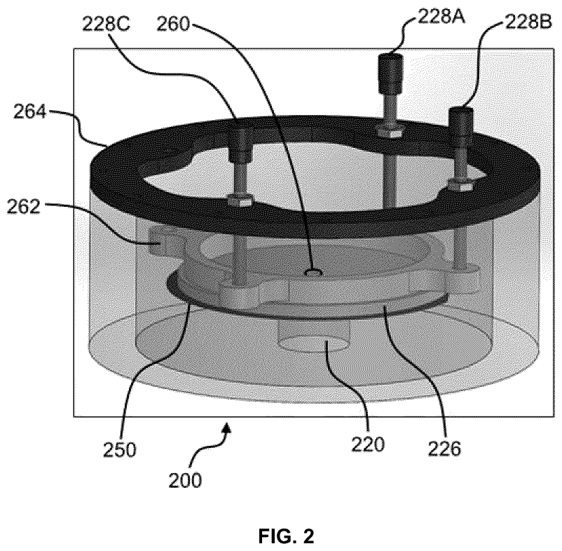

Turning now to FIG. 2, a partial, perspective graphical depiction of a reaction assembly 200 is illustrated according to another embodiment of the present disclosure. A lid 226 may be movable by supporting columns 228A, 228B and 228C vertically or horizontally, and, optionally, may be movable on the horizontal plane via a motor. In some cases, the supporting columns 228 may be adjustment screws. The lid 226 may be transparent so that a naked eye or an instrument may inspect a wafer 250 directly below the lid 226. The wafer 250 may sit on a vacuum chuck (not shown). The vacuum chuck may be configured to support and secure the wafer 250. The vacuum chuck may engage with a shaft 220 which may move the vacuum chuck vertically. As shown in FIG. 2, the lid 226 aligns with the wafer 250 along a vertical axis at the center of and perpendicular to the surface of the wafer 250. The wafer 250 and the bottom surface of the lid 226 are circular. In the center of the lid 226 there may be a hole 260, through which a nozzle and/or an inlet tube can be inserted so that to dispense at least one reagent or solution over the top surface of the wafer 250 in a controlled manner. In addition, a first hanging frame 262 may engage with both the supporting columns 228 and the lid 226. A second hanging frame 264 may engage with secure the supporting columns 228.

Referring to FIG. 3, the relative layout of the lid and the vacuum chuck is further depicted as reaction assembly 300 according to another embodiment of the present disclosure. In the center of a lid 326 there may be a nozzle 352 for controlled delivery of reagents to the top surface of a wafer 350, which is supported and secured by a vacuum chuck 322. The lid 326 is movable with the help of supporting columns 328A and 328B vertically, and optionally movable on the horizontal plane via another motor. The vacuum chuck 322 may sit on and controlled by a supporting shaft 320.

In some embodiments, the reagents can be transferred to the nozzle 352 via a conduit or tube 330 on the top of the lid 326 when the wafer 350 does not spin or when the wafer 350 remains stationary relative to the lid 326. The conduit or tube 330 can transfer gas, liquid or solution at a predetermined rate and in a predetermined amount. The conduit or tube 330 may be washed or gas dried in-between different deliveries of reagents so that contamination of reagents within the conduit or tube 330 is minimized. The delivery of reagents may be air-propelled or pump-controlled. The amount and sequence of reagents to be delivery as well as the rate of delivery may be controlled by an external controller, for example, a computer or a microprocessor.

In some embodiments, when gas is used to deliver the reagents, the gas may be inert gas, such as, for example, nitrogen, argon or other noble gas, or mixture thereof. Other added advantages of using inert gas to deliver reagents may include drying of the conduit or tube 330 between deliveries using the passage of inert gas; protection of air- or moisture-sensitive reagents during delivery; maintaining a positive pressure of inert gas over the top surface of the wafer 350 during chemical synthesis; and removing excess reagents from the surface of the wafer 350 at the end of the chemical reactions, either by evaporation or by pushing the reagents over the edge of the wafer 350. When gas purges over the surface of the wafer 350, the wafer 350 does not spin or the wafer 350 can remain stationary relative to the lid 326.

In some embodiments, when the lid 326 is lowered, the gap distance d between the bottom surface of the lid 326 and the top surface of the wafer 350 can be controlled. The gap distance d between the top surface of the wafer 350 and the bottom surface of the lid 326 may range from about 20 μm to about 2 mm. The diameter of the lid 326 may be the same as the diameter of the wafer 350 it covers, longer than the diameter of the wafer 350, or shorter than the diameter of the wafer 350. In some cases, the diameter of the lid 326 is longer than the diameter of the wafer 350. The diameter of the wafer 350 can be, for example, about 50 mm, about 100 mm, about 150 mm, about 200 mm, about 250 mm, or other lengths.

In some embodiments, reagents in the forms of gas, liquid or solution may be introduced into the conduit or tube 330 in a controlled manner. The nozzle 352 may deliver the reagents onto the top surface of the wafer 350 when the wafer 350 does not spin or when the wafer 350 is stationary relative to the lid 326. Liquid reagents may spread by capillary action or surface tension when the wafer 350 does not spin or when the wafer 350 is stationary relative to the lid 326. The amount of reagents delivered can be calculated or estimated based on the volume of the reaction chamber or the volume of the gap, each of which may depends on the gap distance. After the reaction chamber has been filled with a first solution/reagent, the wafer 350 may remain stationary for at least 30 seconds, at least 40 seconds, at least 50 seconds, at least 60 seconds, at least 70 seconds, at least 80 second, at least 90 seconds, at least 100 seconds, at least 120 seconds, at least 3 minutes, at least 4 minutes, at least 5 minutes, or longer, to allow the solution/reagent to react with each other or other products formed previously in the reaction chamber before the start of the next delivery of a second solution/reagent. The delivered solution/reagent may form a substantially flat surface, e.g., forming a thin-film. The series of arrows with thin arrowheads in FIG. 3 may show the general direction of the reagents in the conduit or tube 330 and the nozzle 352, and the directions of the reagent's flowing patterns once delivered onto the top surface of the wafer 350 due to capillary force or surface tension. In some cases, the solution delivered may comprise one reagent. In other cases, the solution delivered may comprise at least two reagents.

In some embodiments, after the chemical processing of the wafer is completed, the wafer may be dried by continuous inert air flow. When the wafer is considered dry enough, turning back to FIG. 1, the vacuum applied by the vacuum chuck 22 may be relieved. Then the wafer conveyance robot 16 may remove the processed wafer from the top of the vacuum chuck 22 to the inside of wafer cassette 12B for storage. Finally, the wafer conveyance robot 16 may be ready to remove another wafer from wafer cassette 12A for another round of wafer processing.

In some embodiments, as shown and explained above, a robotically operated system has been disclosed to achieve automated high-throughput fabrication of wafers with minimal user intervention according the methods disclosed. Alternatively, the wafer conveyance robot may be replaced with a wafer track for wafer transferring tasks.

Further, in some embodiments, an independently controlled chemical delivery system via the lid may be used to deliver different chemical solutions/reagents onto the center of the surface of the wafer. Excessive heat or gaseous by-products of the surface reactions may be dispersed by a continuous flow of inert gas either through the chemical delivery system or via a separate gas inlet/outlet system.

In one embodiment, the lid may have about the same diameter as the wafer below the lid so that the bottom surface of the lid and the top surface of the wafer may form a semi-enclosed reaction chamber in-between the two surfaces. Chemical reactions may happen in this semi-enclosed reaction chamber. In FIG. 3, the gap distance between the two surfaces is represented by the symbol “d”. The volume of the reaction chamber may be estimated by the surface area of the wafer times the separation gap between the two surfaces: Volume=A_{wafer}×d_{gap}, wherein A_{wafer} is the surface area of the wafer, and d_{gap} is the gap distance between the two surfaces. This Volume can be considered as, approximately, the volume of reagents in the chemical process over the surface of the wafer because the wafer can accommodate such a volume of each solution/reagent added, according to the present disclosure. For example, if the diameter of the wafer is about 150 mm and the separation gap is about 0.5 mm, the volume of the semi-enclosed reaction chamber is about 8 mL. This volume of the reaction chamber is a reduction in reagent volume when compared with puddle drop systems used for polymer resist development. In the puddle drop systems, the volume of reagent used is determined by the meniscus caused by surface tension. Moreover, if reagents used are volatile or sensitive to ambient air or moisture, for example, when phosphoramidite reagents are used, the semi-enclosed reaction chamber according to the present disclosure may minimize evaporation and reduce contamination because only the outer edge of the thin film layer of the solutions/reagents in the reaction chamber on top of the wafer may be in contact with ambient air. The exposed surface of the reagent may be: Area of exposure=π×d_{wafer}×d_{gap}, wherein d_{wafer} is the diameter of the wafer. The Area of exposure may be significantly smaller than that when no lid or cover stays close to the wafer since the top surface of the thin film on the wafer of the present disclosure is not exposed to ambient air when the lid of the present disclosure is present.

In some cases, the reagents dispensed on the surface of the wafer may permeate the reaction chamber and cover the surface of the wafer by capillary action or surface tension, thereby improving uniformity of distribution of the reagents across the surface of the wafer. In addition, the movement of liquid against a stationary bottom surface of the lid can provide some reagent mixing. Alternatively, relief patterns can be implemented on the bottom surface of the lid, or ultrasonic module(s) can be added to the reaction chamber, so that reagent mixing can be improved.

In some embodiments, the degree of uniformity of distribution of reagents over the top surface of the wafer may be of key importance to the quality of the wafer after the chemical processing. The degree of uniformity of distribution of the reagents may relate to various factors, wherein, to some extent, the structure of the device enclosing the reaction chamber may determine the uniformity of distribution. For example, for the reaction chamber disclosed in the present disclosure, if the bottom surface of the lid and the top surface of the wafer are kept substantially parallel and the solution of more than two reagent has been thoroughly mixed before dispensed on to the top surface of the wafer, the degree of uniformity of distribution may be high because the reaction chamber thus formed, may be completely filled with a solution which comprises reagents uniformly mixed before reaching the nozzle in the lid. Due to the small volume of the reaction chamber and the presence of surface tension/capillary effect associated with the dispersed solutions/agents, the solutions/reagents once dispersed on the top surface of the wafer may spread laterally in the radial direction of the wafer, thereby realizing the uniform distribution of the solutions/reagents over the top surface of the wafer.

In addition, in some embodiments, uniformly distributed reagents may enhance the efficiency of reactions between the distributed reagents. For example, when several reactions in sequence are required in chemical processing of the wafer, the overall yield of the reactions may rely on or be influenced by the uniformity of distribution of reagents in each step. A non-uniformed distribution of reagents may lead to waste of reagents in the sense that one reagent may be locally more concentrated or more diluted than another reagent so that each reagent may have a fraction thereof remaining unreacted in the end. These unreacted reagents in each step may produce low overall yield for the chemical process.

Further, in some embodiments, because the wafer remains stationary relative to the lid when the solutions/reagents are dispensed over the top surface of the wafer, the only force pushing the solutions/reagents over the edge of the wafer may be the addition of more solutions/reagents via the nozzle. When the nozzle stops dispensing solutions/reagents, there is no force from the center of the wafer to push the solutions/reagents near the edge outward. Gravity may cause some material loss near the edge. But surface tension may keep the solutions/reagents remain in the reaction chamber due to the small size of the gap distance of the reaction chamber. As a result, there may require/use less solutions/reagents because the “wasted” faction of solutions/reagents that is pushed over the edge of the wafer may be less in the present disclosure when compare with other procedures. Moreover, the device/system of the present disclosure may be fully automated by using a processor or computer to control the moving of the wafer and the dispensing of solutions/reagents, etc. These characteristics may be advantageous over other devices/systems/methods, such as, for example, chemical synthesis in a flow-cell reactor, which allows solution/reagents to flow through the corresponding reaction chamber, or chemical synthesis on a microwell microarray plate, which requires the construction of microwell on the plate before the DNA synthesis.

In some cases, there is no outlet port for the delivered chemicals. Excess chemicals can be pushed off the edge by the delivery of the next chemical reagent, pushed through by a puff of a processing inert gas, or any combination of the above methods. Further, process optimization to control the volume of reaction added or vacuum chuck design with a chemical waste collection portion underneath the vacuum chuck can prevent used or discarded chemicals from dripping onto the bottom surface of the wafer. In addition, additional outlet(s) may be added at the base 10 in FIG. 1 to remove spun-off or discarded chemicals. Similarly, at the completion of the wafer processing, the wafer can be inert-gas dried with a wider, pre-determined separation gap between the two surfaces, dried at an elevated temperature, or a combination of the above. Alternatively, an outlet tube can be inserted into the lid away from the nozzle and the tube (i.e. the inlet tube to deliver reagents) connected to the nozzle. The outlet tube may be configured to suck up excess reagents, used up reagents, or reagents remained in liquid forms in a controlled manner (for example, after a predetermined time of reacting) and transport the sucked-up reagents to a waste container. For example, vacuum can be applied to the outlet tube in the lid to suck up reagents. Then the next reagent can be delivered via the inlet tube in the lid and the nozzle to fill the reaction chamber.

In some cases, the lid can be cleaned with a flow of wash solution/solvent through the separation gap prior to drying of the bottom surface of the lid or the addition of solutions/reagents for the next step. This may ensure minimal contamination between process steps or cross-contamination of reagents.

In some cases, for oligonucleotide synthesis application of the present disclosure, flexible 3/16″ OD FEP tubing may be used to deliver reagents to a glass lid, both of which are inert to the solvents used in the oligonucleotide synthesis. Further, as an example, a separation gap of about 0.5 mm may be implemented when delivering reagents to the top surface of the wafer with an about 150 mm diameter so that about 8 mL of reagent volume may be expected to fill the reaction chamber defined by the bottom surface of the lid and the top surface of the wafer. All chemical reagent manipulations can be controlled by an external oligo-synthesizer or an event management system, which may communicate with the reaction chamber to perform desired tasks, including but not limited to, setting up the gap distance, the amount and speed of each reagent delivery, the flow rate and duration of inert gas, etc.

In some cases, solvents used as part of chemical processing may include but not be limited to: DI water, acetonitrile (ACN), trichloromethane (TCM), and THF. The wafer can be a glass wafer. The lid can be a glass lid. The shape of the dispenser may include but not be limited to: circular and square.

In some cases, before the addition of the solutions/reagents during the chemical process, the supporting columns for the lid can be adjusted manually, mechanically, or automatically in order to make the opposing surfaces of the wafer and the lid parallel and to make the glass lid on top of the wafer centered at the central axis of the wafer.

In some embodiments, photo-cleavable groups (PCG) may be put on the 5′-OH group of phosphoramidite reagents. For example, compounds of Formula I may be used in oligonucleotide synthesis methods disclosed in the present disclosure:

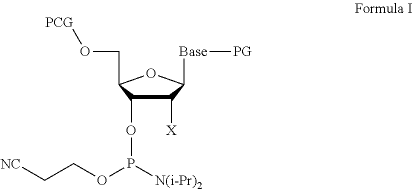

wherein PCG is a photo-cleavable group; X is H (for DNA synthesis) or a protected 2′-hydroxy group (for RNA synthesis); Base is a nucleic acid base or nucleobase including but not limited to: adenine (A), cytosine (C), guanine (G), thymine (T), and uracil (U), or analogs thereof; and PG is none, or a protecting group on reactive groups (for example, N atom or O atom) on the Base. In particular, PG may include but not be limited to N-benzoyl (Bz), N-acetyl (Ac), N-isobutyryl (iBu), N-phenoxyacetyl (PAC), N-tert-butylphenoxyacetyl (tBPAC), 4-methoxy-7-nitroindolinyl (MNI), I-nitrobenzyl (O—NB), 3-(4,5-dimethoxy-2-nitrophenyl)2-butyl (DMNPB), and 4-carboxymethoxy-5,7-dinitroindoinyl (CDNI). Further, PCG may include but not be limited to 5′-(α-methyl-2-nitropiperonyl)oxycarbonyl (MeNPOC), 2-(2-nitrophenyl)propoxycarbonyl (NPPOC), dimethoxybenzoincarbonate (DMBOC), and thiophenyl-2-(2-nitrophenyl)-propoxycarbonyl (SPh-NPPOC), the structures of which are shown below:

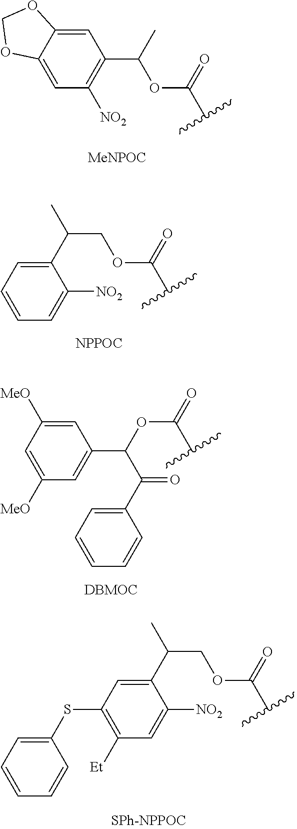

Examples of some PCG can be found in Mayer, G. and Heckel, A., “Biologically active molecules with a ‘light switch’,” Angew. Chem., Int. Ed., 2006; 45(30), pp. 4900-4921, which is entirely incorporated herein by reference. Examples of some photosensitive chemical moieties may include ortho-nitrobenzyloxy linkers, ortho-nitrobenzylamino linkers, alpha-substituted ortho-nitrobenzyl linkers, ortho-nitroveratryl linkers, phenacyl linkers, para-alkoxyphenacyl linkers, benzoin linkers, or pivaloyl linkers. See R. J. T. Mikkelsen, “Photolabile Linkers for Solid-phase Synthesis,” ACS Comb. Sci. 2018; 20(7):377-399; S. Peukert and B. Giese, “The Pivaloylglycol Anchor Group: A New Platform for a Photolabile Linker in Solid-Phase Synthesis,” J. Org. Chem. 1998, 63(24): 9045-9051, each of which is entirely incorporated herein by reference.

### Example 1: Probes Construction

The following is an example describing generally how to construct probes using the device/system/method of the present disclosure.
(1) Surface treatment. A substrate can be surface modified to provide primary alcohols. Any one of a variety of methods described previously, can be used (see, e.g., U.S. Pat. No. 5,959,098—“Substrate preparation process;” J. Am. Chem. Soc. 1997, 119(22), 5081—“The efficiency of light-directed synthesis of DNA arrays on glass substrates;” U.S. Pat. No. 6,262,216—“Functionalized silicon compounds and methods for their synthesis and use;” U.S. Pat. No. 8,105,821—“Silane mixtures;” U.S. Patent Pub. No. 2013165350 Al—“Surface Linkers for Array Synthesis”). For example, the substrate can be silanated by treatment with a solution comprising a mixture of N-(2-hydroxyethyl)-N,N-bis(3-(trimethoxysilyl)propyl)amine and N-(2-cyanoethyl)-N,N-bis(3-(trimethoxysilyl)propyl)amine (ratio from about 1:0 to about 1:20, with a total silane concentration from 1-10% w/v) in ethanol for 1-8 hours. After silanation, the silanated substrate can be rinsed with ethyl alcohol, water, and finally dried. The substrate is ready for array synthesis. In some cases, the substrate can be silicon that has been silanated with a 65 nm layer of SiO₂. Other substrates, such as fused silica with suitable primary alcohol base layers can be used as well. The surface primary alcohols thus obtained can provide the anchor points for attachment to hexaethylene glycol (HEG) linker.
(2) HEG linkage. A DNA “chip maker” can be assembled to conduct surface chemistry on a substrate. For example, the substrate can be placed a device/system of the present disclosure, which can be connected to an automated oligonucleotide synthesizer (after replacing the conventional reaction column of the synthesizer with a device/system of the present disclosure). Then reagents can be added sequentially to the substrate surface, using standard solid-phase oligonucleotide synthesis protocols. The reagents added may include, but not be limited to, linkers such as reagents to insert a hexaethylene glycol (HEG) linker, 5′-DMT-protected-3′-O-phosphoramidites (DMT is 4,4′-dimethoxytrityl), or 5′-PCG-protected-3′-O-phosphoramidites, fluorophore-linked phosphoramidites, coupling activators (e.g., 0.5 M tetrazole in acetonitrile), or oxidizing reagents (e.g., 0.05 M iodine in acetonitrile/pyridine/water (7:1:2, v/v/v)), etc. This can be followed by a washing step by solvents, or a DMT deprotection step using trichloroacetic acid, dichloroacetic acid, or other acids in a solvent (e.g., dichloromethane) to expose the 5′-alcohol group, or a deblocking step of the PCG group on another machine using light radiation under a photolithographic mask. See, e.g., J. Am. Chem. Soc. 1997, 119(22), 5081—“The efficiency of light-directed synthesis of DNA arrays on glass substrates;” Methods in Molecular Biology, 2001, 170, 71, Rampal JB, ed.—“Photolithographic synthesis of high-density oligonucleotide arrays;” Current Protocols in Nucleic Acid Chemistry 2005, 12:12.5.1-12.5.10—“DNA Microarray Preparation by Light-Controlled In Situ Synthesis.” In this way, DNA sequences can be attached to the surface of the wafer.

Examples of automated DNA synthesizer can be, for example, Eppendorf D200 automated synthesizer, Amersham Pharmacia OligoPilot II, PE Biosystem ABI 3948 and Expedite 8909, or MerMade oligonucleotide synthesizer. Using the DNA “chip maker” the silanated substrate obtained in Step (1) with surface primary alcohols can be treated with a surface modification reagent, for example, 18-O-dimethoxytritylhexaethyleneglycol,1-[(2-cyanoethyl)-(N,N-diisopropyl)]-phosphoramidite (Glen Research Corp., Virginia, USA), followed by oxidation to make the phosphate and the removal of the DMT protecting group, to attach the phosphate diester end of the HEG linker to the surface of the silanated substrate and leave a free primary alcohol on the other end of the HEG linker.

In all DNA synthesizer-based surface chemistry conducted using a device/system according to the present disclosure, the solutions/reagents can be added via the nozzle to the top surface of the substrate when the substrate does not spin or when the substrate remains stationary relative to the lid.
(3) Oligonucleotide synthesis. Using the DNA “chip maker” a single PCG-protected nucleotide or DMT-protected nucleotide can be added to the primary alcohols on the substrate, depending on the need of the experiments. For example, following standard DNA automated synthesis protocols and using DMT-nucleoside phosphoramidite reagents, DMT-protected nucleotides can be sequentially added to a primary alcohol on the substrate to provide a desired DNA sequence in the end. When fluorophore attachment is desired, a PCG-nucleoside phosphoramidite, such as a compound of Formula I, can be added to the HEG linker or the previously synthesized DNA sequence. For example, a compound of Formula I, wherein the Base is thymine, the PG is none, and the PCG is MeNPOC, can be added as the last nucleotide in the HEG-linked DNA sequence on the substrate.
(4) Photo cleavage. The substrate comprising PCG-protected DNA sequence obtained in Step (3) can be removed from the DNA “chip maker” and transferred to a device for photolithography treatment. The substrate can be directly imaged through a photo-lithographic mask in a suitable mask aligner (e.g., an ABM mask aligner (ABM, Inc., Silicon Valley, CA)) and at the appropriate dose (e.g., about 720 mJ/cm² at 365 nm). Some PCG groups may be removed in the presence of solvent/base when radiated by light. Some PCG groups do not need the presence of solvent/base when radiated by light. In the end, a 5′-OH group on the DNA sequence can become available for the attachment of fluorescent labels.
(5) Fluorophore attachment. The substrate with the PCG group removed from 5′ position can be put back to the DNA “chip maker”. Using the DNA “chip maker” the free 5′OH group on the DNA sequence can react with fluorophore-bearing phosphoramidite or a mixture of fluorophore-bearing phosphoramidite and DMT-nucleoside phosphoramidite. For example, when 5′-fluorescein phosphoramidite (6-(3′, 6′-dipivaloylfluoresceinyl-6-carboxamido)-hexyl-1-O-(2-cyanoethyl)-(N,N-diisopropyl)-phosphoramidite, 5′-fluorescein CEP, BA 0054, Berry and Associates) is used, a molar ratio of about 1:20 for 5′-fluorescein phosphoramidite to 5′-DMT-thymine phosphoramidite can be obtained by diluting 5′-fluorescein CEP to 2.5 mM in a 50 mM solution of 5′-DMT-T phosphoramidite in acetonitrile. Then standard DNA automated synthesis protocols can be followed to attach the fluorescein label to the DNA sequence on the substrate, followed by oxidation to make the phosphate. Other fluorophore labels can be attached.
(6) Deprotection. The final deprotection of the synthesized, protected oligonucleotide can be done by treating the protected oligonucleotide with 50% ethylenediamine in water (v:v) for about 3 hours, rinsed in deionized water, then dried.
(7) Imaging. All fluorescence data and images can be collected by a confocal microscope, a chip reader, a biochip scanner, or a microarray reader. For example, the substrate can be viewed with a Bio-Rad 9Bio-Rad Laboratories, Hercules, CA) MRC-1024 laser scanning confocal microscope using an appropriate wavelength as the excitation source, an appropriate bandpass filter in front of a photomultiplier tube to collect the emission from the fluorophore, e.g., fluorescein. Images may be acquired using direct-mode and/or time-domain Kalman filtering of image frames. In some cases, the images can be taken by a KEYENCE microscope (KEYENCE Corp. of America, Itasca, IL). In some cases, the fluorescence imaging can be performed on dry substrates, in fluorescein excitation/emission channel. Each image may allow exposure for about 1 second in the high resolution mode. All images to be analyzed can be taken at 40× magnification. After the solution/reagent is dispersed onto the surface of the wafer, capillary force spreads the solution/reagent over the surface of the wafer. In some cases, the wafer does not require spinning during the addition of the solutions/reagents. In some cases, additional addition of solutions/regents happens at least 80 seconds after the completion of the addition of the solutions/reagents.

### Example 2: Probe Construction Using Flow-Cell

The same procedure in Example 1 is modified to use a flow cell instead of the device/system of the present disclosure for probe construction. Oligonucleotide synthesis conditions, such as, for example, reaction time, temperature, concentration of reagents, etc., can be kept the same as in Example 1, unless expressly stated otherwise.

Surface treatment step for the wafer can be the same as in Example 1. HEG linkage step and oligonucleotide synthesis step can be done by a DNA “chip maker” assembled from a sealed flow-cell, which can be connected to an automated oligonucleotide synthesizer (after replacing the conventional reaction column of the synthesizer with a customized flow cell). When a flow cell reaction chamber is used, standard manipulation of the substrates can be followed when conducting surface chemistry, including shaking, turning, agitating the substrate inside the flow cell reaction chamber. Photo cleavage step can be the same. Fluorophore attachment step and deprotection step can be done by the DNA “chip maker” comprising the sealed flow-cell. Finally, imaging step can be the same.

Comparison of the images obtained in Examples 1 and 2 may display the difference in the quality and quantity of synthesized oligonucleotide using the device/system/method of the present disclosure and those of the flow-cell.

Uniform fluorescence signals may reflect uniform reaction conditions and/or uniform reagent distribution on the surface of the substrate while conducting oligonucleotide synthesis. In some cases, surface wetting of the reagents/solutions may spread the liquid form in a thin uniform layer throughout the wafer/lid interface, thereby ensuring uniform reaction conditions without physical disturbance since the wafer does not spin or the wafer remained stationary relative to the lid. In some cases, the thickness of the thin layer thus formed on the surface of the substrate may be more uniform because the physical constraints imposed by the wafer/lid on the reaction chamber may be stricter than those in the control flow-cell. In some cases, precise parallelism between wafer/lid may be achieved by capillary action in the wetting process, thereby physically imposing the boundaries for the thin film formed on the surface of the substrate.

### INDUSTRIAL APPLICATION OF THE PRESENT DISCLOSURE

The device/system/method of the present disclosure may exhibit the following characteristics:
thin uniform layer of oligonucleotide on the surface of the wafer due to surface wetting of the reagent, thereby ensuring uniform reaction conditions for oligonucleotide synthesis;
high reaction efficiency for surface chemistry related to oligonucleotide synthesis;
uniform fluorescence signals for probes obtained from oligonucleotide synthesis;
strong fluorescence signals for probes;
easy implementation to ensure parallelism between the wafer and the lid during oligonucleotide synthesis;
less waste in reagents since less material is lost due to spinning or other physical motions of the substrate during the oligonucleotide synthesis process, and smaller reaction chamber when compared with a flow-cell;
automatable process for handling the wafer and sealing the reaction chamber;
simplified equipment design for a stationary or no-spinning wafer during oligonucleotide synthesis; and
cost saving due to less waste in reagents and the simplified equipment design.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

1. A wafer processing apparatus, comprising:
(a) a lower portion; and
(b) an upper portion, the upper portion comprising:
a bowl affixed to the lower portion;
a vacuum chuck disposed in the bowl, the vacuum chuck configured to rotatably hold a wafer;
a movable cover disposed above the bowl and configured to engage with the bowl;
a lid connected with the movable cover and disposed between the bowl and movable cover, the lid comprising a nozzle at the center of the lid; and
three or more adjustment pins, wherein each member of the three or more adjustment pins inserted through an aperture in the movable cover, attached to the lid, and configured to adjust the position of the lid relative to the wafer;
wherein the lid and the wafer define a reaction chamber between a bottom surface of the lid and a top surface of the wafer; and wherein the movable cover and the bowl are configured to enclose the vacuum chuck, the wafer, the lid, and the reaction chamber.

2. The wafer procession apparatus of claim 1, wherein the upper portion further comprises an actuator configured to open/close the movable cover.

3. The wafer processing apparatus of claim 1, further comprising a fluidic system comprising a conduit inserted through the movable cover and the lid, and configured to dispense at least one reagent into the reaction chamber via the nozzle.

4. The wafer processing apparatus of claim 1, wherein the upper portion further comprises a wafer centering mechanism configured to adjust the position of the wafer, thereby keeping the wafer rotating about a rotation axis of the vacuum chuck.

5. The wafer processing apparatus of claim 1, further comprising a wafer conveyance robot configured to place the wafer onto the vacuum chuck and remove the wafer from the vacuum chuck.

6. The wafer processing apparatus of claim 1, wherein the lid is radially smaller than the wafer.

7. The wafer processing apparatus of claim 1, wherein at least part of the lid is transparent.

8. The wafer processing apparatus of claim 1, wherein at least part of the movable cover is transparent.

9. The wafer processing apparatus of claim 1, further comprising at least one processor configured to control the operation of the movable cover, the vacuum chuck, the lid, the fluidic system, the wafer conveyance robot, the wafer centering mechanism, or a combination thereof.

10. The wafer processing apparatus of claim 9, wherein the at least one processor is configured to open/close the movable cover, load/unload the wafer, position the lid, dispense the at least one reagent, synchronize the fluid system, the actuator and the vacuum chuck, or a combination there of.

11. A method for processing wafers, comprising:
(a) placing a wafer on top of a vacuum chuck of a wafer processing apparatus, the wafer processing apparatus further comprising:
(i) a lower portion; and
(ii) an upper portion, the upper portion comprising:
a bowl affixed to the lower portion;
a movable cover disposed above the bowl and engaged with the bowl;
a lid connected with the movable cover and disposed between the bowl and movable cover, the lid comprising a nozzle at the center of the lid; and
three or more adjustment pins, wherein each member of the three or more adjustment pins inserted through an aperture in the movable cover, attached to the lid;
wherein the vacuum chuck is disposed in the bowl, the vacuum chuck configured to rotatably hold the wafer;
(b) closing the movable cover, thereby enclosing the wafer in a closed space formed by the movable cover and the bowl;
(c) adjusting any of the three or more adjustment pins, thereby making a bottom surface of the lid and the top surface of the wafer substantially parallel and forming a reaction chamber between the bottom surface of the lid and the top surface of the wafer, wherein the width of the reaction chamber ranges from 20 micrometer to 200 micrometer; and
(d) dispensing at least one reagent into the reaction chamber by a nozzle; thereby substantially fill up the reaction chamber.

12. The method of claim 11, wherein in (d) the wafer is stationary during the dispending of the at least one reagent.

13. The method of claim 11, further comprising, after (d): (e) dispensing an inert gas into the reaction chamber.

14. The method of claim 13, wherein in (e) the wafer is stationary during the dispensing of the inert gas.

15. The method of claim 13, wherein in (e) the wafer is spinning during the dispensing of the inert gas.

16. The method of claim 11, further comprising, after (d): adjusting the position of the wafer relative to a rotation axis of the vacuum chuck by a centering mechanism, thereby keeping the wafer rotating about a rotation axis of the vacuum chuck.

17. The method of claim 11, further comprising, after (d): opening the movable cover and removing the wafer from the vacuum chuck.

18. The method of claim 11, further comprising: controlling, by at least one processor, the placing in (a), the closing in (b), the adjusting any of the three or more adjustment pins in (c), the dispensing in (d), the adjusting the position of the wafer after (d), the opening the movable cover after (d), and the removing the wafer after (d).

19. The method of claim 18, wherein the placing in (a) and the removing the wafer after (d) is done by a wafer conveyance robot.

20. The method of claim 19, wherein the at least one processor synchronizes and repeats a plurality of times of the placing in (a), the closing in (b), the adjusting any of the three or more adjustment pins in (c), the dispensing in (d), the adjusting the position of the wafer after (d), the opening the movable cover after (d), and the removing the wafer after (d).

21. The method of claim 11, further comprising: creating a plurality of features on the wafer; detecting signals corresponding to each of the plurality of features on the wafer by fluorescence microscopic imaging; wherein the signals display a smaller variation when compared to signals generated from a corresponding wafer made in a flow cell.

22. The method of claim 11, wherein the at least one reagent comprises a phosphoramidite reagent.

23. The method of claim 22, further comprising: repeating (a), (b), (c), (d), thereby creating a plurality of oligonucleotides on different features of the wafer.


SEQUENCE LISTING (2 sequences)

SEQ ID NO: 1 - DNA, 10 bp, synthetic construct
  source 1..10: mol_type = other DNA; note = Synthetic Oligonucleotide
tttttttttt

SEQ ID NO: 2 - DNA, 20 bp, synthetic construct
  source 1..20: mol_type = other DNA; note = AM1 sequence
cgacatagccgacttagcat